(19) United States
(12) Patent Application Publication
(10) Pub. No.: US 2024/0365640 A1
(43) Pub. Date: Oct. 31, 2024

(54) DISPLAY DEVICE

(71) Applicant: Samsung Display Co., Ltd., Yongin-si (KR)

(72) Inventors: KYUNGHOE LEE, Yongin-si (KR); MUKYUNG JEON, Yongin-si (KR); CHEOL-GON LEE, Yongin-si (KR)

(21) Appl. No.: 18/627,270

(22) Filed: Apr. 4, 2024

(30) Foreign Application Priority Data
Apr. 27, 2023 (KR) 10-2023-0055466

(51) Int. Cl. H10K 59/65; G06V 40/13; H10K 59/131; H10K 59/80

(52) U.S. Cl. CPC H10K 59/65; G06V 40/1306; H10K 59/131; H10K 59/873

(57) ABSTRACT

A display device includes: a display panel including: an active area; a peripheral area adjacent to the active area; a circuit layer including a plurality of insulation layers including: at least one lower insulation layer; and at least one upper insulation layer including an inorganic material; and an element layer including a plurality of light emitting elements in the active area, and a plurality of light sensing elements in the active area. The peripheral area includes an open area in which the at least one upper insulation layer is not disposed, and the circuit layer includes: a plurality of readout lines electrically connected with the plurality of light sensing elements, and extending from the active area to the peripheral area; and an inorganic insulation pattern overlapping with the open area and at least a portion of the plurality of readout lines.

### CROSS-REFERENCE TO RELATED APPLICATION

The present application claims priority to and the benefit of Korean Patent Application No. 10-2023-0055466, filed on Apr. 27, 2023, in the Korean Intellectual Property Office, the entire disclosure of which is incorporated by reference herein.

### BACKGROUND

### 1. Field

Aspects of embodiments of the present disclosure relate to a display device, and more particularly, to a display device that may sense a fingerprint.

### 2. Description of the Related Art

A display device displays an image to provide a user with information or provide various functions capable of organically communicating with the user, such as sensing a user input. Recent display devices include a function for sensing information (e.g., biometric information, and the like) provided by the user. As a user information recognition method, there is an electrostatic capacitive method for sensing a change in electrostatic capacitance provided between electrodes, an optical method for sensing incident light using an optical sensor, an ultrasonic wave method for sensing a vibration using a piezoelectric material, and the like.

The above information disclosed in this Background section is for enhancement of understanding of the background of the present disclosure, and therefore, it may contain information that does not constitute prior art.

### SUMMARY

One or more embodiments of the present disclosure are directed to a display device including a sensor that may sense a fingerprint.

According to one or more embodiments of the present disclosure, a display device includes: a display panel including: an active area; a peripheral area adjacent to the active area; a circuit layer including a plurality of insulation layers including: at least one lower insulation layer; and at least one upper insulation layer including an inorganic material; and an element layer including a plurality of light emitting elements in the active area, and a plurality of light sensing elements in the active area. The peripheral area includes an open area in which the at least one upper insulation layer is not disposed, and the circuit layer includes: a plurality of readout lines electrically connected with the plurality of light sensing elements, and extending from the active area to the peripheral area; and an inorganic insulation pattern overlapping with the open area and at least a portion of the plurality of readout lines.

In an embodiment, the circuit layer may further include a first conductive layer under each of the plurality of readout lines; and the inorganic insulation pattern may include a first inorganic insulation pattern between the plurality of readout lines and the first conductive layer.

In an embodiment, the first conductive layer may be configured to be applied with a constant voltage or ground voltage.

In an embodiment, the inorganic insulation pattern may further include a second inorganic insulation pattern over the plurality of readout lines.

In an embodiment, the first inorganic insulation pattern may be directly on the first conductive layer; the plurality of readout lines may be directly on the first inorganic insulation pattern; and the second inorganic insulation pattern may be directly on the plurality of readout lines.

In an embodiment, the circuit layer may further include a second conductive layer over each of the plurality of readout lines; and the second inorganic insulation pattern may be located between the plurality of readout lines and the second conductive layer.

In an embodiment, the second conductive layer may be configured to be applied with a constant voltage or ground voltage.

In an embodiment, the inorganic insulation pattern may further include a third inorganic insulation pattern over the second conductive layer.

In an embodiment, the display panel may further include an encapsulation layer on the element layer, and covering the plurality of light emitting elements and the plurality of light sensing elements. The encapsulation layer may be located on the second conductive layer in the open area.

In an embodiment, the display panel may further include a sensor layer directly on the encapsulation layer, and including at least one sensor conductive layer.

In an embodiment, the second conductive layer may be located between at least a portion of the sensor conductive layer and the plurality of readout lines.

In an embodiment, the circuit layer may further include a plurality of data lines electrically connected to the plurality of light emitting elements, and extending to the peripheral area; and the first conductive layer may be located between the plurality of readout lines and the plurality of data lines.

In an embodiment, the open area may include: a first open area in which the plurality of readout lines overlap with the plurality of data lines; and a second open area in which either the plurality of readout lines, the plurality of data lines, or both do not overlap with each other. The inorganic insulation pattern may overlap with the first open area.

In an embodiment, the plurality of data lines may be covered by the lower insulation layer.

In an embodiment, the circuit layer may further include a dam structure overlapping with the open area, and including at least one layer including the same material as that of the upper insulation layer.

In an embodiment, the peripheral area may further include a bending area bent about a bending axis parallel to one direction; and the open area may be located between the active area and the bending area.

According to one or more embodiments of the present disclosure, a display device includes: a display panel including: an active area; a peripheral area adjacent to the active area; a circuit layer including a plurality of insulation layers and at least one line, the plurality of insulating layers including at least one upper insulation layer including an inorganic material; and an element layer including a plurality of light emitting elements in the active area, and a plurality of light sensing elements in the active area. The peripheral area includes an open area in which the at least one upper insulation layer is not disposed, and the circuit layer includes: a plurality of data lines electrically connected to the plurality of light emitting elements, and extending to the peripheral area; a plurality of readout lines electrically connected with the plurality of light sensing elements, and extending from the active area to the peripheral area; and an inorganic insulation pattern overlapping with the open area, and at least a portion of the inorganic insulation pattern is located between the plurality of data lines and the plurality of readout lines.

According to one or more embodiments of the present disclosure, a display device includes: a display panel including: an active area; a peripheral area adjacent to the active area; a circuit layer including a plurality of insulation layers and at least one line, the plurality of insulation layers including at least one upper insulation layer including an inorganic material; and an element layer including a plurality of light emitting elements in the active area, and a plurality of light sensing elements in the active area. The peripheral area includes an open area in which the at least one upper insulation layer is not disposed, and the circuit layer includes: a plurality of readout lines electrically connected with the plurality of light sensing elements, and extending from the active area to the peripheral area; and an inorganic insulation pattern overlapping with the open area, and contacting at least one of a top surface or a bottom surface of the plurality of readout lines.

In an embodiment, the circuit layer may further include a first conductive layer under each of the plurality of readout lines; and the inorganic insulation pattern may include: a first inorganic insulation pattern between the plurality of readout lines and the first conductive layer; and a second inorganic insulation pattern over the plurality of readout lines.

In an embodiment, the first inorganic insulation pattern may be directly on the first conductive layer; the plurality of readout lines may be directly on the first inorganic insulation pattern; and the second inorganic insulation pattern may be directly on the plurality of readout lines.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of a display device according to an embodiment of the present disclosure;

FIG. 2 is a block diagram of a display device according to an embodiment of the present disclosure;

FIG. 3 is a block diagram of a display layer and a display driver according to an embodiment of the present disclosure;

FIG. 4 is a block diagram of a sensor layer and a sensor driver according to an embodiment of the present disclosure;

FIG. 5 is an equivalent circuit diagram of a pixel and a sensor according to an embodiment of the present disclosure;

FIG. 6 is a cross-sectional view of a display device according to an embodiment of the present disclosure;

FIG. 7 is a plan view of a display panel according to an embodiment of the present disclosure;

FIG. 8 is an enlarged plan view illustrating a portion of a display panel according to an embodiment of the present disclosure;

FIG. 9 is an enlarged cross-sectional view illustrating a portion of a display panel according to an embodiment of the present disclosure;

FIGS. 10A and 10B are enlarged plan views illustrating a portion of a display panel according to one or more embodiments of the present disclosure; and

FIGS. 11A-11E are enlarged cross-sectional views of a portion of a display panel according to one or more embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

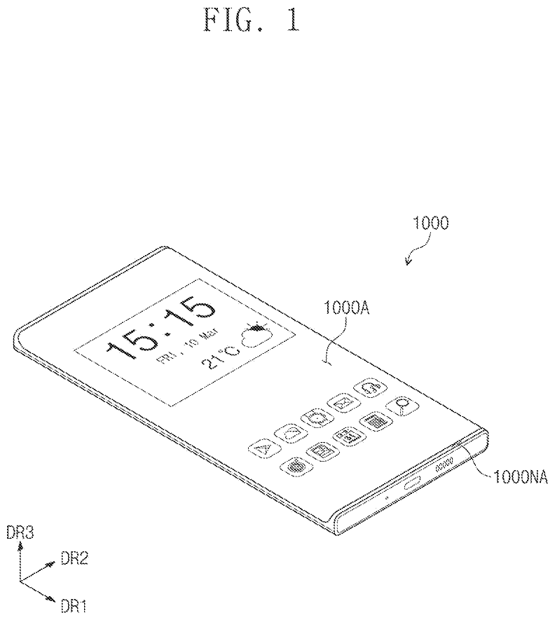

FIG. 1 is a perspective view of a display device 1000 according to an embodiment of the present disclosure.

Referring to FIG. 1, the display device 1000 may be a device activated in response to an electrical signal. For example, the display device 1000 may be a mobile phone, a foldable phone, a television, a tablet, a vehicle navigator, a game device, or a wearable device, but the present disclosure is not limited thereto. For convenience of illustration, in FIG. 1, a mobile phone is shown as a representative example of the display device 1000.

In the display device 1000, an active area 1000A and a peripheral area 1000NA may be defined. The display device 1000 may display an image through the active area 1000A. The active area 1000A may include a surface defined by a first direction DR1 and a second direction DR2. The peripheral area 1000NA may surround around the periphery of the active area 1000A.

The thickness direction of the display device 1000 may be parallel to or substantially parallel to a third direction DR2 that crosses or intersects with the first direction DR1 and the second direction DR2. Accordingly, the front surfaces (e.g., top surfaces) and the rear surfaces (e.g., bottom surfaces) of the members constituting the display device 1000 may be defined on the basis of the third direction DR3.

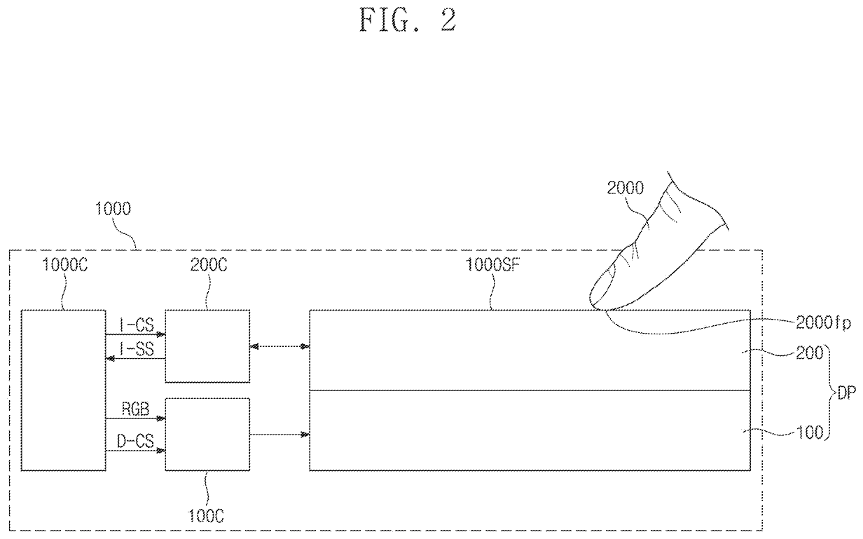

FIG. 2 is a block diagram of the display device 1000 according to an embodiment of the present disclosure.

Referring to FIG. 2, the display device 1000 includes a display panel DP, a display driver 100C, a sensor driver 200C, and a main driver 1000C. The display panel DP may include a display layer 100, and a sensor layer 200 disposed on the display layer 100. In an embodiment of the present disclosure, the sensor layer 200 may be omitted as needed or desired.

The display layer 100 may be a component configured to generate or substantially generate an image. The display layer 100 may be an emissive display layer. For example, the display layer 100 may be an organic light emitting display layer, an inorganic light emitting display layer, an organic-inorganic light emitting display layer, a quantum dot display layer, a micro LED display layer, or a nano LED display layer. In addition, the display layer 100 may include a sensor configured to react to light or detect light reflected by a fingerprint 2000fp of a user.

The sensor layer 200 may be disposed on the display layer 100. The sensor layer 200 may sense an external input 2000 applied from the outside. The external input 2000 may include all suitable input means for providing a change in an electrostatic capacitance. For example, the sensor layer 200 may detect an input from a passive kind of input means, such as the body (e.g., finger) of the user, as well as an active kind of input means for providing a drive signal, for example, such as an active pen.

The main driver 1000C may control the overall operations of the display device 1000. For example, the main driver 1000C may control the operations of the display driver 100C and the sensor driver 200C. The main driver 1000C may include at least one microprocessor, and may further include a graphic controller. The main driver 1000C may be referred to as an application processor, a central processing device, or a main processor.

The display driver 100C may drive the display layer 100. The display driver 1000C may receive image data RGB and a control signal D-CS from the main driver 1000C. The control signal D-CS may include various suitable signals. For example, the control signal D-CS may include an input vertical synchronous signal, an input horizontal synchronous signal, a main clock, a data enable signal, and the like. The display driver 100C may generate a vertical synchronous signal and a horizontal synchronous signal for controlling the timing for providing a signal to the display layer 100 on the basis of the control signal D-CS.

The sensor driver 200C may drive the sensor layer 200. The sensor driver 200C may receive a control signal I-CS from the main driver 1000C. The control signal I-CS may include a mode determination signal and a clock signal that determine a driving mode of the sensor driver 200C.

The sensor driver 200C may calculate coordinate information regarding the input on the basis of a signal received from the sensor layer 200, and may provide a coordinate signal I-SS having the coordinate information to the main driver 1000C. The main driver 1000C may execute an operation corresponding to the user input on the basis of the coordinate signal I-SS. For example, the main driver 1000C may operate the display driver 100C so that a new application image is displayed on the display layer 100.

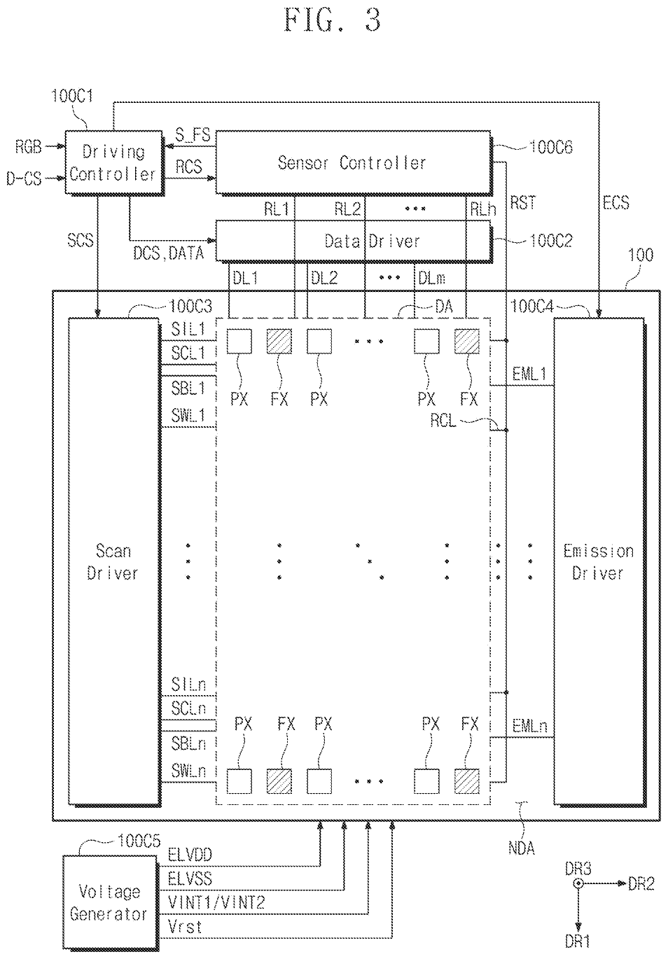

FIG. 3 is a block diagram of the display layer 100 and the display driver 100C according to an embodiment of the present disclosure.

Referring to FIGS. 2 and 3, the display driver 100C may include a driving controller 100C1, a data driver 100C2, a scan driver 100C3, an emission driver 100C4, a voltage generator 100C5, and a sensor controller 100C6.

The display layer 100 may include an active area DA (e.g., a display area) corresponding to the active area 1000A (e.g., see FIG. 1), and a peripheral area NDA (e.g., a non-display area) corresponding to the peripheral area 1000NA.

The display layer 100 may include a plurality of pixels PX disposed in the active area DA, and a plurality of sensors FX disposed in the active area DA. The display layer 100 further includes initialization scan lines SIL1 to SILn, compensation scan lines SCL1 to SCLn, write scan lines SWL1 to SWLn, black scan lines SBL1 to SBLn, emission control lines EML1 to EMLn, data lines DL1 to DLm, and readout lines RL1 to RLh. Here, h, m, and n are each a natural number greater than 1.

The initialization scan lines SIL1 to SILn, the compensation scan lines SCL1 to SCLn, the write scan lines SWL1 to SWLn, the black scan lines SBL1 to SBLn, and the emission control lines EML1 to EMLn extend in the second direction DR2. The initialization scan lines SIL1 to SILn, the compensation scan lines SCL1 to SCLn, the write scan lines SWL1 to SWLn, the black scan lines SBL1 to SBLn, and the emission control lines EML1 to EMLn are spaced apart from each other along the first direction DR1. The data lines DL1 to DLm and the readout lines RL1 to RLh extend in the first direction DR1, and are spaced apart from each other along the second direction DR2.

The plurality of pixels PX are electrically connected to the initialization scan lines SIL1 to SILn, the compensation scan lines SCL1 to SCLn, the write scan lines SWL1 to SWLn, the black scan lines SBL1 to SBLn, the emission control lines EML1 to EMLn, and the data lines DL1 to DLm. For example, each of the plurality of pixels PX may be electrically connected to four scan lines. However, the number of scan lines connected to each of the pixels PX is not limited thereto, and may be variously modified as needed or desired.

The plurality of sensors FX are electrically connected to the readout lines RL1 to RLh. One sensor FX may be electrically connected to one scan line, for example, such as one of the write scan lines SWL1 to SWLn. However, the present disclosure is not limited thereto. The number of scan lines connected to each of the sensors FX may be variously modified as needed or desired.

As an example, the number of readout lines RL1 to RLh may correspond to half of the number of the data lines DL1 to DLm. However, the present disclosure is not limited thereto. As another example, the number of readout lines RL1 to RLh may correspond to ¼, ⅛, or the like of the number of the data lines DL1 to DLm, or the number of readout lines RL1 to RLh may be the same or substantially the same as that of the data lines DL1 to DLm.

The driving controller 100C1 receives the image data RGB and the control signal D-CS. The driving controller 100C1 may generate an image data signal DATA to which the data format of the image data RGB is converted to match an interface specification with the data driver 100C2. The driving controller 100C1 may output a first control signal SCS, a second control signal ECS, a third control signal DCS, and a fourth control signal RCS.

The data driver 100C2 may receive the third control signal DCS and the image data signal DATA from the driving controller 100C1. The data driver 100C2 converts the image data signal DATA into the data signals, and outputs the data signals to the plurality of data lines DL1 to DLm to be described in more detail below. The data signals are analog voltages corresponding to grayscale values of the image data signal DATA.

The scan driver 100C3 may receive the first control signal SCS from the driving controller 100C1. The scan driver 100C3 may output scan signals to the scan lines in response to the first control signal SCS. For example, the scan driver 100C3 outputs, in response to the first control signal SCS, initialization scan signals to the initializations scan lines GIL1 to GILn, and compensation scan signals to the compensation scan lines SCL1 to SCLn. In addition, the scan driver 100C3 may output, in response to the first control signal SCS, write scan signals to the write scan lines SWL1 to SWLn, and black scan signals to the black scan lines SBL1 to SBLn.

The emission driver 100C4 may receive the second control signal ECS from the driving controller 100C1. The emission driver 100C4 may output, in response to the second control signal ECS, emission control signals to the emission control lines EML1 to EMLn. As another example, the scan diver 100C3 may be connected to the emission control lines EML1 to EMLn. In this case, the emission driver 100C4 may be omitted, and the scan driver 100C3 may output the emission control signals to the emission control lines EML1 to EMLn.

The scan driver 100C3 and the emission driver 100C4 may be disposed in the peripheral area NDA of the display layer 100. However, the present disclosure is not limited thereto. For example, at least a portion of each of the scan driver 100C3 and the emission driver 100C4 may be disposed in the active area DA.

The voltage generator 100C5 generates voltages used for the operation of the display panel 100. In the present embodiment, the voltage generator 100C5 generates a first driving voltage ELVDD, a second driving voltage ELVSS, a first initialization voltage VINT1, a second initialization voltage VINT2, and a reset voltage Vrst.

The sensor controller 100C6 may receive the fourth control signal RCS from the driving controller 100C1.

The sensor controller 100C6 may receive, in response to the fourth control signal RCS, sensing signals from the readout lines RL1 to RLh. The sensor controller 100C6 may process the sensing signals received from the readout lines RL1 to RLh, and may provide the processed sensing signals S_FS to the driving controller 100C1.

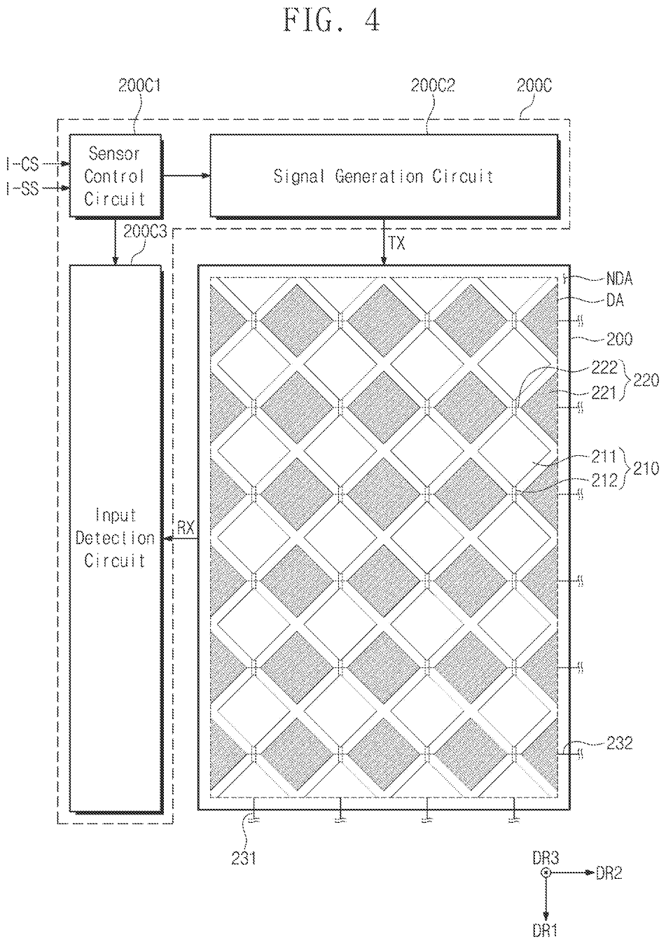

FIG. 4 is a block diagram of the sensor layer 200 and the sensor driver 200C according to an embodiment of the present disclosure.

Referring to FIG. 4, the sensor layer 200 may include a plurality of first sensing electrodes 210 and a plurality of second sensing electrodes 220 disposed in the active area DA. The plurality of second sensing electrodes 220 may cross the plurality of first sensing electrodes 210.

Each of the plurality of first sensing electrodes 210 may extend in the first direction DR1, and may be spaced apart from each other along the second direction DR2. Each of the plurality of second sensing electrodes 220 may extend in the second direction DR2, and may be spaced apart from each other along the first direction DR1.

Each of the plurality of first sensing electrodes 210 may include a sensing pattern 211 and a connection pattern 212. Two adjacent sensing patterns of the sensing patterns 211 may be electrically connected to each other by two of the connection patterns 212, but the present disclosure is not limited thereto. The sensing patterns 211 and the connection patterns 212 may be arranged at (e.g., in or on) different layers from each other.

Each of the plurality of second sensing electrodes 220 may include a first portion 221 and a second portion 222. The first portion 221 and the second portion 222 may have an integral shape, and may be disposed at (e.g., in or on) the same layer as each other. For example, the first portion 221 and the second portion 222 may be disposed at (e.g., in or on) the same layer as that of the sensing patterns 211. The two connection patterns 212 may be insulated from and cross the second portions 222.

The sensor layer 200 may further include a plurality of first trace lines 231 electrically connected to the first sensing electrodes 210, and a plurality of second trace lines 232 electrically connected to the second sensing electrodes 220. The first trace lines 231 and the second trace lines 232 may be arranged in the peripheral area NDA, but the present disclosure is not particularly limited thereto. For example, at least a portion of the first and second trace lines 231, 232 may be disposed to overlap with the active area DA.

The sensor driver 200C may receive a control signal I-CS from the main driver 1000C (e.g., see FIG. 2). The sensor driver 200C may provide a coordinate signal I-SS to the main driver 1000C.

The sensor driver 200C may be implemented with an integrated circuit (IC) to be mounted (e.g., directly mounted) in a desired area (e.g., a prescribed or predetermined area) of the sensor layer 200, or may be mounted on a separate printed circuit board in a chip on film (COF) manner to be electrically connected to the sensor layer 200.

The sensor driver 200C may include a sensor control circuit 200C1, a signal generation circuit 200C2, and an input detection circuit 200C3. The sensor control circuit 200C1 may control the operations of the signal generation circuit 200C2 and the input detection circuit 200C3 on the basis of the control signal I-CS.

The signal generation circuit 200C2 may output transmission signals TX to the first sensing electrodes 210 of the sensor layer 200. The input detection circuit 200C3 may receive the input signals RX from the sensor layer 200. For example, the input detection circuit 200C3 may receive the input signals RX from the second sensing electrodes 220. In an embodiment of the present disclosure, the signal generation circuit 200C2 may output the transmission signals TX to the second sensing electrodes 220 of the sensor layer 200, and the input detection circuit 200C3 may receive the input signals RX from the first sensing electrodes 210.

The input detection circuit 200C3 may convert analog signals to digital signals. For example, the input detection circuit 200C3 may amplify the received analog signals, and may then filter the amplified signals. In other words, the input detection circuit 200C3 may convert the filtered signals to digital signals.

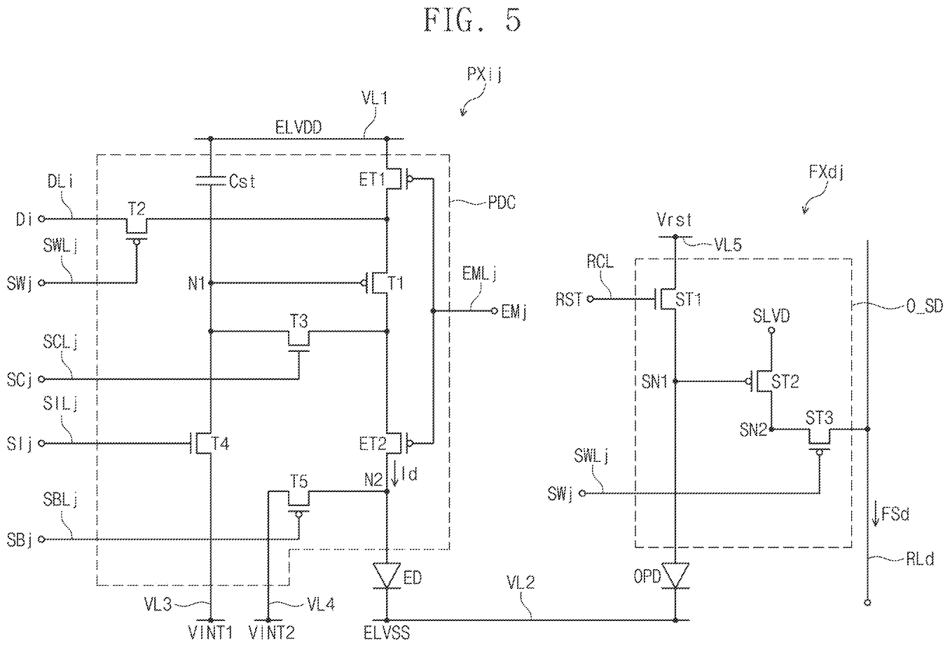

FIG. 5 is an equivalent circuit diagram of a pixel and a sensor according to an embodiment of the present disclosure.

FIG. 5 shows an example equivalent circuit diagram of one pixel PXij from among the plurality of pixels PX (e.g., see FIG. 3). Because the plurality of pixels PX have the same or substantially the same circuit structure as each other, the circuit structure of the pixel PXij will be described in more detail with reference to FIG. 5, and redundant description of the other remaining pixels may not be repeated. In addition, FIG. 5 shows an example equivalent circuit diagram of one sensor FXdj from among the plurality of sensors FX shown in FIG. 3. Because the plurality of sensors FX have the same or substantially the same circuit structure as each other, the circuit structure of the sensor FXdj will be described in more detail with reference to FIG. 5, and redundant description of the other remaining sensors may not be repeated.

Referring to FIGS. 3 and 5, the pixel PXij is connected to an i-th data line DLi from among the data lines DL1 to DLm, a j-th initialization scan line SILj from among the initialization scan lines SIL1 to SILn, a j-th compensation scan line SCLj from among the compensation scan lines SCL1 to SCLn, a j-th write scan line SWLj from among the write scan lines SWL1 to SWLn, a j-th black scan line SBLj from among the black scan lines SBL1 to SBLn, and a j-th emission control line EMLj from among the emission control lines EML1 to EMLn.

The pixel PXij may include a light emitting element ED and a pixel driving circuit PDC. The light emitting element ED may include a light emitting diode. As an example, the light emitting element ED may be an organic light emitting diode including an organic light emitting layer, but the present disclosure is not limited thereto.

The pixel driving circuit PDC includes first to fifth transistors T1, T2, T3, T4, T5, first and second emission control transistors ET1, ET2, and one capacitor Cst.

At least one of the first transistor T1, the second transistor T1, the third transistor T3, the fourth transistor T4, the fifth transistor T5, the first emission control transistor ET1, and/or the second emission control transistor ET2 may be a transistor having a low-temperature polycrystalline silicon (LTPS) semiconductor layer. At least one of the first transistor T1, the second transistor T1, the third transistor T3, the fourth transistor T4, the fifth transistor T5, the first emission control transistor ET1, and/or the second emission control transistor ET2 may be a transistor having an oxide semiconductor layer. For example, the third and fourth transistors T3, T4 may be oxide semiconductor transistors, and the first, second, fifth transistors T1, T2, T5, and the first and second emission control transistors ET1, ET2 may be LTPS transistors.

In more detail, the first transistor T1, which directly influences the brightness of the display device 1000 (e.g., see FIG. 1), may include a semiconductor layer composed of a highly reliable polycrystalline silicon. As such, a display device with high resolution may be implemented. The oxide semiconductor has a high carrier mobility and a low leakage current, and thus, a voltage drop may not be large despite a long driving time. In other words, because a change in color of an image according to the voltage drop may not be large even in low frequency driving, the low frequency driving may be possible. As such, the oxide semiconductor may be desirable for having a small leak current (e.g., a small leakage current), and thus, may be adopted for at least one of the third transistor T3 or the fourth transistor T4, which are connected to a third electrode (e.g., a gate electrode) of the first transistor T1, to prevent or substantially prevent the leak current (e.g., the leakage current) that may flow to the gate electrode, and to reduce power consumption.

A portion (e.g., some) of the first to fifth transistors T1, T2, T3, T4, T5 and the first and second emission control transistors ET1, ET2 may be P-type transistors, and the others may be N-type transistors. For example, the first, second, and fifth transistors T1, T2, T5, and the first and second emission control transistors ET1, ET2 may be P-type transistors, and the third and fourth emission control transistors T3, T4 may be N-type transistors.

The configuration of the pixel driving circuit PDC is not limited to the embodiment shown in FIG. 5. The pixel driving circuit PDC shown in FIG. 5 is provided as an example, and the configuration of the pixel driving circuit PDC may be variously modified as needed or desired. For example, all of the first to fifth transistors T1, T2, T3, T4, T5 and the first and second emission control transistors ET1, ET2 may be P-type transistors or N-type transistors.

The j-th initialization scan line SILj, the j-th compensation scan line SCLj, the j-th write scan line SWLj, the j-th black scan line SBLj, and the j-th emission control line EMLj may transfer, to the pixel PXij, a j-th initialization scan signal SIj, a j-th compensation scan signal SCj, a j-th write scan signal SWj, a j-th black scan signal SBj, and a j-th emission control signal EMj, respectively. The i-th data line DLi delivers an i-th data signal Di to the pixel PXij. The i-th data signal Di may have a voltage level corresponding to the image data RGB (e.g., see FIG. 2) input to the display device 1000. The first and second driving voltage lines VL1 and VL2 may deliver the first voltage ELVDD and the second driving voltage ELVSS, respectively, to the pixel PXij. In addition, the first and second initialization voltage lines VL3 and VL4 may transfer the first initialization voltage VINT1 and the second initialization voltage VINT2, respectively, to the pixel PXij.

The first transistor T1 is connected between the first driving voltage line VL1 for receiving the first driving voltage ELVDD and the light emitting element ED. The first transistor T1 includes a first electrode connected to the first driving voltage line VL1 via the first emission control transistor ET1, a second electrode connected to the light emitting element ED via the second emission control transistor ET2, and a third electrode (e.g., a gate electrode) connected to one terminal (e.g., a first node N1) of the capacitor Cst. The first transistor T1 may receive the i-th data signal Di transferred from the i-th data line DLi in response to a switching operation of the second transistor T2, and may provide a driving current Id to the light emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (e.g., a gate electrode) connected to the j-th write scan line SWLj. The second transistor T2 may be turned on in response to the write scan signal SWj transferred via the j-th write scan line SWLj to transfer the i-th data signal Di transferred from the i-th data line DLi to the first electrode of the first transistor T1.

The third transistor T3 is connected between the first node N1 and the second electrode of the first transistor T1. The third transistor T3 may include a first electrode connected to the third electrode of the first transistor T1, a second electrode connected to the second electrode of the first transistor T1, and a third electrode (e.g., a gate electrode) connected to the j-th compensation scan line SCLj. The third transistor T3 may be turned on in response to the j-th compensation scan signal SCLj transferred via the j-th compensation scan line SCLj to connect the third electrode and the second electrode of the first transistor T1 to each other, and thus, the first transistor T1 may be diode-connected.

The fourth transistor T4 is connected between and the first node N1 and the first initialization voltage line VL3 applied with the first initialization voltage VINT1. The fourth transistor T4 may include a first electrode connected to the first initialization line VL3 for transferring the first initialization voltage VINT1, a second electrode connected to the first node N1, and a third electrode (e.g., a gate electrode) connected to the j-th initialization scan line SILj. The fourth transistor T4 is turned on in response to the j-th initialization scan signal SIj transferred via the j-th initialization scan line SILj. The turned-on fourth transistor T4 transfers the first initialization voltage VINT1 to the first node N1 to initialize a potential of the third electrode (e.g., the potential of the first node N1) of the first transistor T1.

The first emission control transistor ET1 includes a first electrode connected to the first driving voltage line VL1, a second electrode connected to the first electrode of the first transistor T1, and a third electrode (e.g., a gate electrode) connected to the j-th emission control line EMLj.

The second emission control transistor ET2 may include a first electrode connected to the second electrode of the first transistor T1, a second electrode connected to the light emitting element ED, and a third electrode (e.g., a gate electrode) connected to the j-th light emission control line EMLj.

The first and second emission control transistors ET1, ET2 may be concurrently or substantially simultaneously turned on with each other in response to the j-th emission control signal EMj transferred via the j-th emission control line EMLj. The first driving voltage ELVDD applied through the turned-on first emission control transistor ET1 may be compensated for through the diode-connected first transistor T1, and may then be transferred to the light emitting element ED.

The fifth transistor T5 may include a first electrode connected to the second initialization line VL4 for transferring the second initialization voltage VINT2, a second electrode connected to the second emission control transistor ET2, and a third electrode (e.g., a gate electrode) connected to the j-th black scan line SBLj. The second initialization voltage VINT2 may have a level lower than or equal to that of the first initialization voltage VINT1.

As described above, the one terminal of the capacitor Cst is connected to the third electrode of the first transistor T1, and the other terminal is connected to the first driving voltage line VL1. A cathode of the light emitting diode ED may be connected to the second driving voltage line VL2 for transferring the second driving voltage ELVSS. The second driving voltage ELVSS may have a voltage level equal to or lower than that of the first driving voltage ELVDD.

The sensor FX is connected to a d-th readout line RLd from among the readout lines RL1 to RLh, the j-th write scan line SWLj (e.g., referred to as an output control line), and a reset control line RCL.

The sensor FX includes a light sensing element OPD (e.g., referred to as a sensing element) and a sensor driving circuit O_SD.

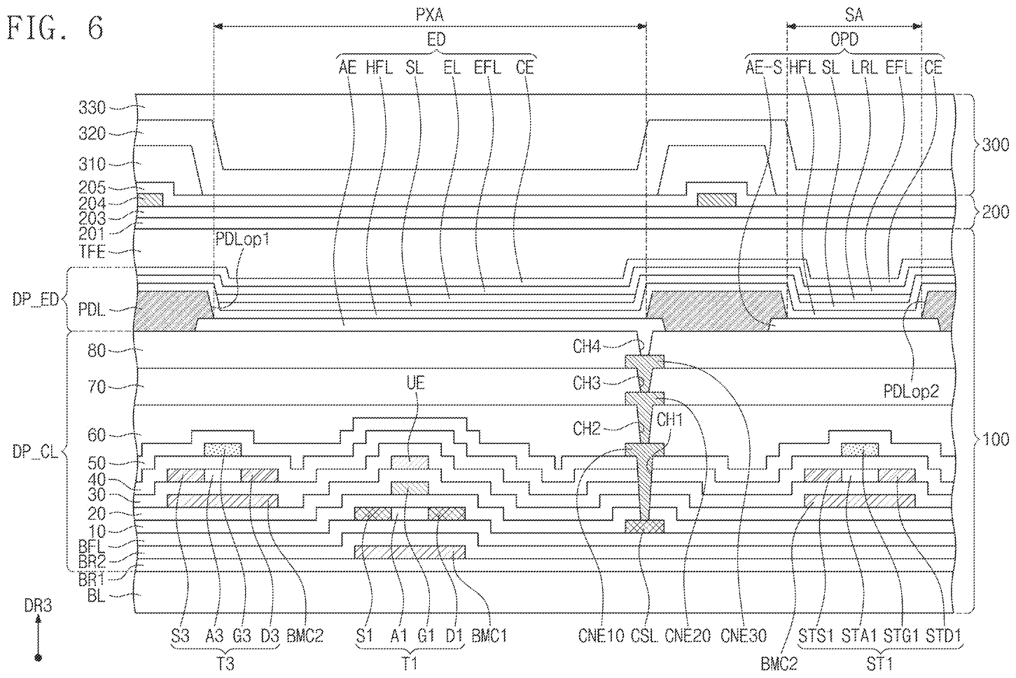

The light sensing element OPD may be a photodiode. As an example, the light sensing element OPD may be an organic photodiode OPD including an organic material as a photoelectric conversion layer. A first electrode AE-S (e.g., see FIG. 6) of the light sensing element OPD may be connected to a first sensing node SN1, and a second electrode CE of the light sensing element OPD may be connected to the second driving voltage line VL2 for transferring the second driving voltage ELVSS. FIG. 5 shows an example in which the sensor FX includes one light sensing element OPD, but the present disclosure is not particularly limited thereto. For example, the sensor FX may include z light receiving elements connected in parallel to each other. Here, z may be an integer of 2 or more.

The sensor driving circuit O_SD includes three transistors ST1, ST2, ST3. The three transistors ST1, ST2, ST3 may include (e.g., may be) a reset transistor ST1, an amplification transistor ST2, and an output transistor ST3. At least one of the reset transistor ST1, the amplification transistor ST2, and/or the output transistor ST3 may be an oxide semiconductor transistor. As an example, the reset transistor ST1 may be an oxide semiconductor transistor, and the amplification transistor ST2 and the output transistor ST3 may be LTPS transistors. However, the present disclosure is not limited thereto, and at least the reset transistor ST1 and the output transistor ST3 may be oxide semiconductor transistors, and the amplification transistor ST2 may be an LTPS transistor.

In addition, at least one of the reset transistor ST1, the amplification transistor ST2, and/or the output transistor ST3 may be P-type transistors, and the other(s) may be an N-type transistor. As an example, the amplification transistor ST2 and the output transistor ST3 may be P-type transistors, and the reset transistor ST1 may be an N-type transistor. However, the present disclosure is not limited thereto, and the reset transistor ST1, the amplification transistor ST2, and the output transistor ST3 may all be N-type transistors, or P-type transistors.

The circuit configuration of the sensor driving circuit O_SD according to one or more embodiments of the present disclosure is not limited to that shown in FIG. 5. The sensor driving circuit O_SD shown in FIG. 5 is provided as an example, and the configuration of the sensor driving circuit O_SD may be variously modified as needed or desired.

The reset transistor ST1 includes a first electrode connected to a third initialization voltage line VL5 for receiving a reset voltage Vrst, a second electrode connected to the first sensing node SN1, and a third electrode (e.g., a gate electrode) for receiving a reset control signal RST. The reset transistor ST1 may reset the potential of the first sensing node SN1 to the reset voltage Vrst in response to the reset control signal RST. The reset control signal RST may be a signal provided through the reset control line RCL.

The amplification transistor ST2 includes a first electrode for receiving the sensing driving voltage SLVD, a second electrode connected to the second sensing node SN2, and a third electrode (e.g., a gate electrode) connected to the first sensing node SN1. The amplification transistor ST2 may be turned on in response to the potential of the first sensing node SN1 to apply the sensing driving voltage SLVD to the second sensing node SN2. As an example, the sensing driving voltage SLVD may be one of the first driving voltage ELVDD and the first and second initialization voltages VINT1, VINT2. When the sensing driving voltage SLVD is the first driving voltage ELVDD, the first electrode of the amplification transistor ST2 may be electrically connected to the first driving voltage line VL1. When the sensing driving voltage SLVD is the first initialization voltage VINT1, the first electrode of the amplification transistor ST2 may be electrically connected to the first initialization voltage line VL3. When the sensing driving voltage SLVD is the second initialization voltage VINT2, the first electrode of the amplification transistor ST2 may be electrically connected to the second initialization voltage line VL4.

The output transistor ST3 includes a first electrode connected to the second sensing node SN2, a second electrode connected to the d-th readout line RLd, and a third electrode (e.g., a gate electrode) for receiving an output control signal via the output control line. The output transistor ST3 may transfer a sensing signal Fsd to the d-th readout line RLd in response to the output control signal. The output control signal may be the j-th write scan signal SWj (e.g., referred to as a j-th output control signal) supplied through the j-th write scan line SWLj. In other words, the output transistor ST3 may receive, as the output control signal, the j-th write scan signal SWj supplied from the j-th write scan line SWLj.

The reset period may be defined as an activation period (e.g., a high level period) of the reset control line RCL. When the reset control signal RST of a high level is supplied through the reset control line RCL, the reset transistor ST1 is turned on. As another example, when the reset transistor ST1 is configured with a PMOS transistor, the reset control signal RST of a low level may be supplied to the reset control line RCL during the reset period. During the reset period, the first sensing node SN1 may be reset to a potential corresponding to the reset voltage Vrst. As an example, the reset voltage Vrst may have a lower voltage level than that of the second driving voltage ELVSS.

The light sensing element OPD of the sensor FX may be exposed to light during the emission period of the light emitting element ED. The voltage of the first sensing node SN1 is maintained or substantially maintained as the reset voltage Vrst in the reset period, and as the light sensing element OPD is exposed to light, the voltage of the first sensing node SN1 may be gradually shifted to the second driving voltage ELVSS. The amplification transistor ST2 may be source-follower amplifier configured to generate a source-drain current in proportion to a charge amount of the first sensing node SN1, which is input to the third electrode of the amplification transistor ST2.

The output transistor ST3 in the output period may receive the j-th write scan signal SWj of a low level through the j-th write scan line SWLj. When the output transistor ST3 is turned on in response to the j-th write scan signal SWj of the low level, the sensing signal Fsd corresponding to the current flowing through the amplification transistor ST2 may be output to the d-th readout line RLd.

FIG. 6 is a cross-sectional view of a display device according to an embodiment of the present disclosure.

Referring to FIG. 6, the display layer 100 may include a base layer BL, and a circuit layer DP_CL, an element layer DP_ED, and an encapsulation layer TFE that are sequentially disposed on the base layer BL.

At least one inorganic layer is provided on the top surface of the base layer BL. The inorganic layer may include at least one of aluminum oxide, titanium oxide, silicon oxide, silicon nitride, silicon oxynitride, zirconium oxide, or halfnium oxide. The inorganic layer may be provided with multiple layers. The multiple inorganic layers may configure barrier layers BR1, BR2, and/or a buffer layer BFL to be described in more detail below. The barrier layers BR1 and BR2, and the buffer layer BFL may be optionally disposed.

The barrier layers BR1, BR2 prevent or substantially prevent a foreign matter from entering from the outside. The barrier layers BR1 and BR2 may include a silicon oxide layer and a silicon nitride layer. The silicon oxide layer and silicon nitride layer may each be provided in a plurality, and the silicon oxide layers and the silicon nitride layers may be alternately stacked on each other.

The barrier layers BR1 and BR2 may include a first barrier layer BR1 and a second barrier layer BR2. A first rear-surface metal layer BMC1 may be disposed between the first barrier layer BR1 and the second barrier layer BR2. In an embodiment of the present disclosure, the first rear-surface metal layer BMC1 may be omitted as needed or desired.

The buffer layer BFL may be disposed on the barrier layers BR1 and BR2. The buffer layer BFL may enhance a bonding force between the base layer BL and a semiconductor pattern and/or a conductive pattern. The barrier layer BFL may include silicon oxide layers and silicon nitride layers. The silicon oxide layers and the silicon nitride layers may be alternately stacked on each other.

The first semiconductor pattern may be disposed on the buffer layer BFL. The first semiconductor pattern may include a silicon semiconductor. For example, the silicon semiconductor may include amorphous silicon, polycrystalline silicon, or the like. For example, the first semiconductor pattern may include low temperature polysilicon.

FIG. 6 illustrates a portion of the first semiconductor pattern disposed on the buffer layer BFL, and other portions of the first semiconductor pattern may be further disposed in other areas. The first semiconductor pattern may be arrayed in a suitable rule (e.g., a specific or predetermined rule) across the pixels. The first semiconductor pattern may have different electrical properties according to whether it is doped or not. The first semiconductor pattern may include a first area having a higher or high conductivity and a second area having a lower or low conductivity. The first area may be doped with an N-type dopant or a P-type dopant. A P-type transistor includes a doped region doped with the P-type dopant, and an N-type transistor includes a doped area doped with the N-type dopant. The second area may be a non-doped area, or may be an area doped at a lower concentration relative to the first area.

The first area may have a greater conductivity than that of the second area, and may operate or substantially operate as an electrode or a signal line. The second area may correspond to or substantially correspond to an active area (or a channel) of a transistor. In other words, a portion of the first semiconductor pattern may be the active area of the transistor, another portion may be a source or a drain, and another portion may be a connection electrode or a signal connection line.

The first electrode S1, the active area A1, and the second electrode D1 of the first transistor T1 are provided from the first semiconductor pattern. The first electrode S1 and the second electrode D1 of the first transistor T1 extend from the semiconductor region A1 in opposite directions.

FIG. 6 illustrates a portion of the connection signal line CSL provided from the first semiconductor pattern. The connection signal line CSL may be connected to the second electrode of the fifth transistor T5 (e.g., see FIG. 5) and the second emission control transistor ET2 in a plan view.

A first insulation layer 10 may be disposed on the buffer layer BFL. The first insulation layer 10 may commonly overlap with the plurality of pixels, and may cover the first semiconductor pattern. The first insulation layer 10 may include an inorganic layer and/or an organic layer, and may have a single layer or multilayered structure. The first insulation layer 10 may include at least one of aluminum oxide, titanium oxide, silicon oxide, silicon nitride, silicon oxynitride, zirconium oxide, or halfnium oxide. In the present embodiment, the first insulation layer 10 may be a single silicon oxide layer. In addition to the first insulation layer 10, an insulation layer of a circuit layer DP_CL to be described in more detail below may also include an inorganic layer and/or an organic layer, and may have a single layer or multilayered structure. The inorganic layer may include at least one of the aforementioned materials, but the present disclosure is not limited thereto.

The third electrode G1 of the first transistor T1 may be disposed on the first insulation layer 10. The third electrode G1 may be a portion of a metal pattern. The third electrode G1 of the first transistor T1 may overlap with the active area A1 of the first transistor T1. The third electrode G1 of the first transistor T1 may function as a mask in a process of doping the first semiconductor pattern. The third electrode G1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), or the like, but the present disclosure is not particularly limited thereto.

The second insulation layer 20 may be disposed on the first insulation layer 10, and may cover the third electrode G1 of the first transistor T1. The second insulation layer 20 may include an inorganic layer and/or an organic layer, and may have a single layer or multilayered structure. The second insulation layer 20 may include at least one of silicon oxide, silicon nitride, or silicon oxynitride. In the present embodiment, the second insulation layer 20 may have a multilayered structure including a silicon oxide layer and a silicon nitride layer.

An upper electrode UE and a second rear-surface metal layer BMC2 may be disposed on the second insulation layer 20. The upper electrode UE may overlap with the third electrode G1. The upper electrode UE may be a portion of a metal pattern. A portion of the third electrode G1 and the upper electrode UE overlapping therewith may define the capacitor Cst (e.g., see FIG. 5). In an embodiment of the present disclosure, the second insulation layer 20 may be displaced by an insulation pattern. In this case, the upper electrode UE may be disposed on the insulation pattern, and the upper electrode UE may serve as a mask configured to provide the insulation pattern from second insulation layer 20.

The second rear-surface metal layer BMC2 may be disposed under an oxide thin-film transistor, for example, such as the third transistor T3. The second rear-surface metal layer BMC2 may be applied with a constant voltage or a signal.

A third insulation layer 30 may be disposed on the second insulation layer 20, and may cover the upper electrode UE and the second rear-surface metal layer BMC2. The third insulation layer 30 may have a single layer or multilayered structure. For example, the third insulation layer 30 may have a multilayered structure including a silicon oxide layer and a silicon nitride layer.

A second semiconductor pattern may be disposed on the third insulation layer 30. The second semiconductor pattern may include an oxide semiconductor. The oxide semiconductor may include a plurality of areas that are divided according to whether or not a metal oxide is reduced. An area (hereinafter, a reduction zone) in which the metal oxide is reduced has a high or higher conductivity in comparison to an area (hereinafter, a non-reduction zone) in which the metal oxide is not reduced. The reduction zone may serve or substantially serve as a source/drain or a signal line of the transistor. The non-reduction zone may correspond to or substantially correspond to the active area (or a semiconductor area, a channel, or the like) of the transistor. In other words, a portion of the second semiconductor pattern may be the active area of the transistor, another portion may be a source/drain area of the transistor, and another portion may be a signal transfer area.

A first electrode S3, the active area A3, and a second electrode D3 of the third transistor T3 are provided from the second semiconductor pattern. The first electrode S3 and the second electrode D3 may include a metal reduced from a metal-oxide-semiconductor. The first electrode S3 and the second electrode D3 may extend from the active area A3 in opposite directions in a cross-sectional view.

A fourth insulation layer 40 may be disposed on the third insulation layer 30. The fourth insulation layer 40 may commonly overlap with the plurality of pixels, and may cover the second semiconductor pattern. The fourth insulation layer 40 may include at least one of aluminum oxide, titanium oxide, silicon oxide, silicon nitride, silicon oxynitride, zirconium oxide, or halfnium oxide.

A third electrode G3 of the third transistor T3 may be disposed on the fourth insulation layer 40. The third electrode G3 may be a portion of a metal pattern. The third electrode G3 of the third transistor T3 may overlap with the active area A3 of the third transistor T3. The third electrode G3 may function as a mask in a process of reducing the second semiconductor pattern. In an embodiment of the present disclosure, the fourth insulation layer 40 may be replaced by an insulation pattern.

A fifth insulation layer 50 may be disposed on the fourth insulation layer 40, and may cover the third electrode G3. The fifth insulation layer 50 may be an inorganic layer.

A first connection electrode CNE10 may be disposed on the fifth insulation layer 50. The first connection electrode CNE10 may be connected to the connection signal line CSL through a first contact hole CH1 penetrating through the first to fifth insulation layers 10, 20, 30, 40, 50.

A sixth insulation layer 60 may be disposed on the fifth insulation layer 50. The sixth insulation layer 60 may be an organic layer. The organic layer may include a general purpose polymer such as Benzocyclobutene (BCB), a polyimide, Hexamethyldisiloxane (HMDSO), or Polystyrene (PS), a polymer derivative having a phenolic group, an acrylic-based polymer, an imide-based polymer, an arylene ether-based polymer, an amide-based polymer, a fluorinated polymer, a p-xylene-based polymer, a vinyl alcohol-based polymer, or a suitable blend thereof, but the present disclosure is not particularly limited thereto.

A second connection electrode CNE20 may be disposed on the sixth insulation layer 60. The second connection electrode CNE20 may be connected to the first connection electrode CNE10 through a second contact hole CH2 penetrating through the sixth insulation layer 60. A seventh insulation layer 70 may be disposed on the sixth insulation layer 60, and may cover the second connection electrode CNE20. The seventh insulation layer 70 may be an organic layer.

A third connection electrode CNE30 may be disposed on the seventh insulation layer 70. The third connection electrode CNE30 may be connected to the second connection electrode CNE20 through a third contact hole CH3 penetrating through the seventh insulation layer 70. An eighth insulation layer 80 may be disposed on the seventh insulation layer 70, and may cover the third connection electrode CNE30. The eighth insulation layer 80 may be an organic layer.

The circuit layer DP_CL may further include the sensor driving circuit O_SD (e.g., see FIG. 5). For the convenience of illustration, the reset transistor ST1 in the sensor driving circuit O_SD is shown in FIG. 6. A first electrode STS1, an active area STA1, and a second electrode STD1 of the reset transistor ST1 are provided from the second semiconductor pattern. The first electrode STS1 and the second electrode STD1 may include a metal reduced from a metal-oxide-semiconductor. The fourth insulation layer 40 is disposed to cover the first electrode STS1, the active area STA1, and the second electrode STD1 of the reset transistor ST1. A third electrode STG1 of the reset transistor ST1 is disposed on the fourth insulation layer 40. In the present embodiment, the third electrode STG1 may be a portion of the metal pattern. The third electrode STG1 of the reset transistor ST1 overlaps with the active area STA1 of the reset transistor ST1.

As an example, the reset transistor ST1 may be disposed at (e.g., in or on) the same layer as that of the third transistor T3. In other words, the first electrode STS1, the active area STA1, and the second electrode STD1 of the reset transistor ST1 may be provided through the same or substantially the same processes as those of the first electrode S3, the active area A3, and the second electrode D3 of the third transistor T3. The third electrode STG1 of the reset transistor ST1 may be concurrently or substantially simultaneously provided through the same or substantially the same process as that of the third electrode G3 of the third transistor T3. The first and second electrodes of the amplification transistor ST2 and the output transistor ST3 of the sensor driving circuit O_SD may be provided through the same or substantially the same processes as those of the first electrode S1 and the second electrode D1 of the first transistor T1. The reset transistor ST1 and the third transistor T3 may be provided at (e.g., in or on) the same layer as each other through the same or substantially the same processes, thereby, not requiring additional processes for providing the reset transistor ST1, and thus, process efficiency may be increased and costs may be reduced.

The element layer DP_ED may be disposed on the circuit layer DP_CL. The element layer DP_ED may include light emitting elements ED and photosensitive light sensing elements OPD. In FIG. 6, one light emitting element ED and one light sensing element OPD are representatively shown.

A light emitting area PXA may be defined in correspondence to the light emitting element ED, and a sensing area SA may be defined in correspondence to the photosensitive light sensing element OPD. The light emitting area PXA and the sensing area SA may each be defined by a pixel definition layer PDL.

The light emitting element ED may include a first electrode AE, a first functional layer HFL, a light emitting layer EL, a second functional layer EFL, and a second electrode CE. The light sensing element OPD may include a first electrode AE-S, a first functional layer HFL, a photoelectric conversion layer LRL, a second functional layer EFL, and a second electrode CE. The first functional layer HFL, the second functional layer EFL, and the second electrode CE may each be commonly provided to the pixels PX (see FIG. 3) and the sensors FX.

Referring to FIG. 6, the first electrode AE of the light emitting element ED and the first electrode AE-S of the light sensing element OPD are disposed on the eighth insulation layer 80. The first electrode AE of the light emitting element ED may be connected to the third connection electrode CNE30 through a fourth contact hole CH4 that penetrates through the eighth insulation layer 80.

The light emitting element ED may further include an auxiliary layer SL. The auxiliary layer SL may be commonly disposed in the light emitting area PXA and the sensing area SA. The auxiliary layer SL may be disposed between the first functional layer HFL and the light emitting layer EL, and between the first functional layer HFL and the photoelectric conversion layer LRL. In an embodiment of the present disclosure, the auxiliary layer SL may be omitted as needed or desired.

The pixel definition layer PDL may be disposed on the eighth insulation layer 80, and may cover portions of each of the first electrodes AE, AE-S. Openings PDLop1, PDLop2 may be provided in the pixel definition layer PDL. The plurality of light emitting areas PXA and the plurality of sensing areas SA may be defined by the openings PDLop1, PDLop2.

The light emitting area PXA may be defined by a first opening PDLop1, and the sensing area SA may be defined by a second opening PDLop2. The first opening PDLop1 may expose at least a portion of the first electrode AE of the light emitting element ED, and the second opening PDLop2 may expose at least a portion of the first electrode AE-S of the light sensing element OPD.

In an embodiment of the present disclosure, the pixel definition layer PDL may further include a black material. The pixel definition layer PDL may further include a black organic dye/pigment such as carbon black, or aniline black. The pixel definition layer PDL may be provided with a mixture of a blue organic material and a black organic material. The pixel definition layer PDL may include a lyophobic organic material.

The light emitting layer EL of the light emitting element ED may be disposed in an area corresponding to the first opening PDLop1. The light emitting layer EL may generate a desired color of light (e.g., a prescribed or predetermined colored light). In the present embodiment, an example of a patterned light emitting layer EL is illustrated in FIG. 6, but the present disclosure is not limited thereto, and one light emitting layer may be commonly disposed in the plurality of light emitting areas. In this case, the light emitting layer may generate white light or blue light. In addition, the light emitting layer may have a multilayered structure referred to as tandem.

The light emitting layer EL may include, as a light emitting material, a low molecular organic material or a high molecular organic material. As another example, the light emitting layer EL may include quantum dots as a light emitting material. The core of the quantum dot may be selected from among a group II-VI compound, a group III-V compound, a group IV-VI compound, a group IV element, a group IV compound, and/or a suitable combination thereof.

The photoelectric conversion layer LRL may be disposed in an area corresponding to the second opening PDLop2. The photoelectric conversion layer LRL may include an organic photosensitive material. The second electrode CE may be disposed on the photoelectric conversion layer LRL. The first electrode AE-S and the second electrode CE may each receive an electric signal. The first electrode AE-S and the second electrode CE may receive signals different from each other. Accordingly, an electric field (e.g., a prescribed or predetermined electric field) may be formed between the first electrode AE-S and the second electrode CE. The photoelectric conversion layer LRL may generate an electric signal corresponding to light incident to the sensor.

Charges generated in the photoelectric conversion layer LRL may change the electric field between the first electrode AE-S and the second electrode CE. The amount of the charges generated in the photoelectric conversion layer LRL may vary according to whether or not light is incident to the light sensing element OPD, and the amount and intensity of light incident to the light sensing element OPD. Accordingly, the electric field formed between the first electrode AE-S and the second electrode CE may vary. The light sensing element OPD according to one or more embodiments of the present disclosure may acquire fingerprint information of a user through a change in the electric field between the first electrode AE-S and the second electrode CE.

The element layer DP_ED may further include a capping layer disposed on the second electrode CE. The capping layer may serve to enhance the light emission efficiency according to a principle of constructive interference. The capping layer may include a suitable material having a refractive index of 1.6 or greater with respect to light of a wavelength of, for example, 589 nm. The capping layer may be an organic capping layer including an organic material, an inorganic capping layer including an inorganic material, or a composite capping layer including organic and inorganic materials. For example, the capping layer may include a heterocyclic compound, an amine group-containing compound, a porphine derivative, a phthalocyanine derivative, a naphthalocyanine derivative, an alkali metal complex, an alkaline earth metal complex, or any suitable combinations thereof. The carbocyclic compound, the heterocyclic compound, and the amine group-containing compound may be optionally substituted with a substituent including O, N, S, Se, Si, F, Cl, Br, I, or any suitable combinations thereof.

The encapsulation layer TFE is disposed on the element layer DP_ED. The encapsulation layer TFE includes an inorganic layer and/or an organic layer. In an embodiment of the present disclosure, the encapsulation layer TFE may include two inorganic layers, and an organic layer interposed therebetween. In an embodiment of the present disclosure, a thin-film encapsulation layer may include a plurality of inorganic layers and a plurality of organic layers that are alternately stacked on each other.

The inorganic encapsulation layer protects the light emitting element ED and the light sensing element OPD from moisture/oxygen, and the organic encapsulation layer protects the light emitting element ED and the light sensing element OPD from foreign matters, such as dust particles. The inorganic encapsulation layer may include a silicon nitride layer, a silicon oxynitride layer, a silicon oxide layer, a titanium oxide layer, aluminum oxide layer, or the like, but the present disclosure is not particularly limited thereto. The organic encapsulation layer may include an acrylic-based organic layer, but the present disclosure is not particularly limited thereto.

The display device 1000 (e.g., see FIG. 1) may further include a sensor layer 200 and an anti-reflection layer 300.

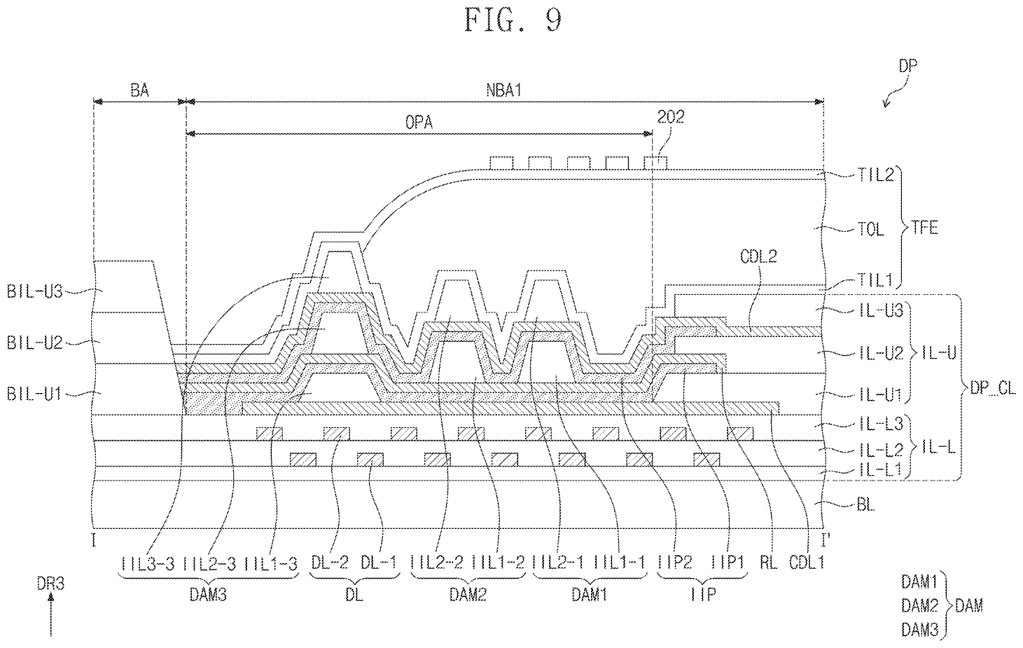

The sensor layer 200 may be disposed on the display layer 100. The sensor layer 200 may sense an external input applied from the outside. The external input may be a user input. The user input includes various suitable kinds of external inputs, for example, such as a part of a user's body (e.g., finger), a pen, light, heat, pressure, and/or the like. The sensor layer 200 may be referred to as a sensor, an input sensing layer, or an input sensing panel. The sensor layer 200 may include a sensor base layer 201, a first sensor conductive layer 202 (e.g., see FIG. 9), a sensor insulation layer 203, a second sensor conductive layer 204, and a sensor cover layer 205.

The sensor base layer 201 may be directly disposed on the display layer 100. The sensor base layer 201 may be an inorganic layer including at least one of silicon nitride, silicon oxynitride, or silicon oxide. As another example, the sensor base layer 201 may be an organic layer including an epoxy resin, an acrylic resin, or an imide-based resin. The sensor base layer 201 may have a single layer structure, or a multilayered structure including multiple layers stacked on one another along the third direction DR3.

Each of the first sensor conductive layer 202 and the second sensor conductive layer 204 may have a single layer structure, or a multilayered structure including multiple layers stacked on one another along the third direction DR3.

The conductive layer of the single layer structure may include a metal layer or a transparent conductive layer. The metal layer may include molybdenum, silver, titanium, copper, aluminum, or a suitable alloy thereof. The transparent conductive layer may include a transparent conductive oxide, such as indium tin oxide, Indium zinc oxide, zinc oxide, or indium-zinc-tin oxide. The transparent conductive layer may include a conductive polymer such as PEDOT, a metal nano-wire, graphene, or the like.

The conductive layer of the multilayered structure may include a plurality of metal layers. For example, the metal layers may have a three-layered structure of titanium/aluminum/titanium. The conductive layer of the multilayered structure may include at least one metal layer and at least one transparent conductive layer.

The sensor insulation layer 203 may be disposed between the first sensor conductive layer 202 and the second sensor conductive layer 204. The sensor insulation layer 203 may include an inorganic film. The inorganic film may include at least one of aluminum oxide, titanium oxide, silicon oxide, silicon nitride, silicon oxynitride, zirconium oxide, or halfnium oxide.

As another example, the sensor insulation layer 203 may include an organic film. The organic film may include at least one of an acrylic-based resin, a methacrylic-based resin, polyisoprene-base resin, a vinyl-based resin, an epoxy-based resin, a urethane-based resin, a cellulose-based resin, a siloxane-based resin, a polyimide based-resin, a polyamide-resin, or a parylene-based resin.

The sensor cover layer 205 may be disposed on the sensor insulation layer 203, and may cover the second sensor conductive layer 204. The second sensor conductive layer 204 may include a conductive pattern. The sensor cover layer 205 may cover the conductive pattern, and may reduce or remove a probability that the conductive pattern is damaged in subsequent processes. The sensor cover layer 205 may include an inorganic material. For example, the sensor cover layer 205 may include silicon nitride, but the present disclosure is not particularly limited thereto. In an embodiment of the present disclosure, the sensor cover layer 205 may be omitted as needed or desired.

The anti-reflection layer 300 may be disposed on the sensor layer 200. The anti-reflection layer 300 may include a division layer 310, a plurality of color filters 320, and a planarization layer 330.

The division layer 310 may be disposed to overlap with the conductive pattern of the second sensor conductive layer 204. The sensor cover layer 205 may be disposed between the division layer 310 and the second sensor conductive layer 204. The division layer 310 may prevent or substantially prevent reflection of external light on the second conductive layer 204. A material defining the division layer 310 may be used without limitation, so long as the material absorbs light. The division layer 310 is a layer having black color, and in an embodiment, may include a black coloring agent. The black coloring agent may include a black dye or a black pigment. The black coloring agent may include carbon black, a metal such as chromium, or an oxide thereof.

A plurality of division openings may be defined in the division layer 310. The plurality of division openings may overlap with the light emitting layer EL and the photoelectric conversion layer LRL. The color filters 320 may be disposed corresponding to the plurality of division openings. The color filters 320 may transmit light provided from the light emitting layer EL overlapping with the color filters 320. As another example, light is transmitted through the color filters 320 to be provided to the photoelectric conversion layer LRL.

The light emitting layer EL may be a green light emitting layer. Accordingly, one color filter 320 may be commonly provided in the light emitting layer EL and the photoelectric conversion layer LRL. However, the present disclosure is not limited thereto. For example, a color filter of a color other than (e.g., different from) green may be disposed on the photoelectric conversion layer LRL. As another example, the color filters 320 may not be disposed on the photoelectric conversion layer LRL.

The planarization layer 330 may cover the division layer 310 and the color filters 320. The planarization layer 330 may include an organic material, and may provide a planar or substantially planar surface on the top surface of the planarization layer 330. In an embodiment of the present disclosure, the planarization layer 330 may be omitted as needed or desired.

In an embodiment of the present disclosure, the anti-reflection layer 300 may include a reflection adjustment layer instead of the color filters 320. For example, the color filters 320 illustrated in FIG. 6 may be omitted, and the reflection adjustment layer may be added at the positions where the color filters 320 are omitted. The reflection adjustment layer may selectively absorb light in a desired band (e.g., a partial or predetermined band) of light reflected inside the display panel and/or an electronic apparatus, or light incident from the outside of the display panel and/or the electronic apparatus.

As an example, the reflection adjustment layer may absorb light in a first wavelength band of about 490 nm to about 505 nm and in a second wavelength band of about 585 nm to 600 nm to cause the light transmittance to be about 40% or smaller in the first wavelength band and the second wavelength band. The reflection adjustment layer may absorb light of wavelengths outside the wavelength ranges of red, green, and blue light emitted from the light emitting layer EL. As such, the reflection adjustment layer may prevent, minimize, or reduce a reduction in luminance of the display panel and/or the electronic apparatus by absorbing light of wavelengths that do not belong to the wavelength ranges of the red, green, or blue light emitted from the light emitting layer EL. In addition, degradation of the light emission efficiency of the display panel and/or electronic apparatus may also be prevented, minimized, or reduced, and the visibility may be improved.

The reflection adjustment layer may be provided with an organic material layer including a dye, a pigment, or a suitable combination thereof. The reflection adjustment layer may include a Tetraazaporphyrin (TAP)-based compound, a Porphyrin-based compound, a Metal Porphyrin-based compound, an Oxazine-based compound, a Squarylium-based compound, a Triarylmethane-based compound, a Polymethine-based compound, an anthraquinone-based compound, a Phthalocyanine-based compound, an azo-based compound, a perylene-based compound, a Xanthene-based compound, a diimmonium-based compound, a Dipyrromethene-based compound, a Cyanine-based compound, or a suitable combination thereof.

In an embodiment, the reflection adjustment layer may have a light transmittance of about 64% to about 72%. The light transmittance of the reflection adjustment layer may be adjusted according to the content of the dye and/or the pigment included in the reflection adjustment layer.

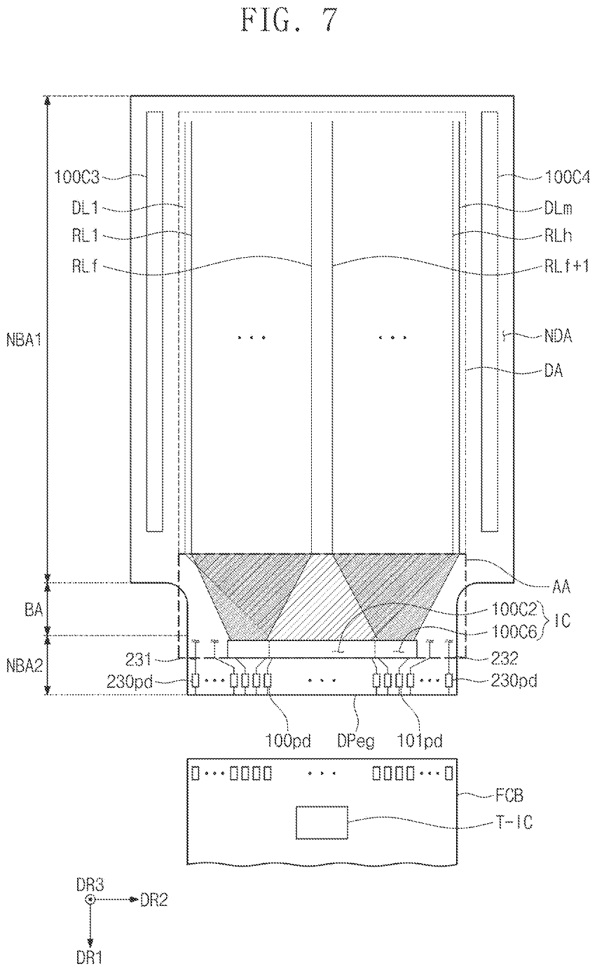

FIG. 7 is a plan view of the display panel DP according to an embodiment of the present disclosure.

Referring to FIGS. 3 and 7, the data lines DL1 to DLm and the readout lines RL1 to RLh may be disposed in the active area DA and the peripheral area NDA. The data lines DL1 to DLm may be electrically connected to the plurality of pixels PX in the active area DA, and may extend to the peripheral area NDA. The readout lines RL1 to RLh may be electrically connected to the plurality of sensors FX in the active area DA, and may extend to the peripheral area NDA.

In an embodiment of the present disclosure, the data lines DL1 to DLm and the readout line RL1 to RLh may extend from the active area DA towards the peripheral area NDA that is adjacent to the active area DA in the first direction DR1. Accordingly, a driver for driving the sensors FX and a driver for driving the pixels PX may be disposed at positions spaced apart (e.g., separated) from each other in one direction on the basis of the active area DA.

In this case, in comparison to a comparative example in which the data lines DL1 to DLm and the readout lines RL1 to RLh extend towards different directions with the active area DA interposed therebetween, the area of a fanout area may be reduced, and the area of the peripheral area NDA may be reduced. In addition, because only a portion of the peripheral area NDA positioned in a lower end portion is bent on the basis of the active area DA, interference between the bent portion of the display panel DP and other sensors (e.g., a position sensor, a vibration sensor, and/or the like) disposed in the bottom of the display panel DP may be reduced. In other words, when the data lines DL1 to DLm and the readout lines RL1 to RLh extend towards the peripheral area NDA positioned in the same direction on the basis of the active area DA, it may become a more beneficial structure in productization of the display panel DP including the sensor FX.

At least a portion of the data lines DL1 to DLm and a portion of the readout lines RL1 to RLh in the peripheral area NDA may overlap with each other. The data lines DL1 to DLm and the readout lines RL1 to RLh may be disposed at (e.g., in or on) different layers from each other. For example, the data lines DL1 to DLm may be disposed at (e.g., in or on) the same layer as that of the third electrode G1 of the first transistor T1, the upper electrode UE, or the third electrode G3 of the third transistor T3 shown in FIG. 6. The readout lines RL1 to RLh may be disposed at (e.g., in or on) the same layer as that of the second connection electrode CNE20 shown in FIG. 6. The disposition relationship between the readout lines RL1 to RLh and the data lines DL1 to DLm in the peripheral area NDA will be described in more detail below.

In the display panel DP according to an embodiment, a portion of the display panel DP may be bent. The display panel DP may include a first non-bending area NBA1, a second non-bending NBA2 spaced apart from the first non-bending area NBA1 in the first direction DR1, and a bending area BA defined between the first non-bending area NBA1 and the second non-bending area NBA2. The first non-bending area NBA1 may include the active area AA and a partial (e.g., part of the) peripheral area NDA. The peripheral area NDA may include the bending area BA and the second non-bending area NBA2.

The bending area BA may be bent along a virtual axis extending in the second direction DR2. When the bending area BA is bent, the second non-bending area NBA2 may face (or be opposite to) the first non-bending area NBA1. In more detail, the bending area BA may be bent so that the second non-bending area NBA2 is positioned under the first non-bending area NBA on the basis of the third direction DR3. In the display panel DP according to an embodiment, the width of the bending area BA in the second direction DR2 may be smaller than that of the first non-bending area NBA1 in the second direction DR2. The width of the second non-bending area NBA2 in the second direction DR2 may be smaller than that of the first non-bending area NBA1 in the second direction DR2.

A driving chip IC may be mounted on the display panel DP, and may be connected to each of the data lines DL1 to DLm and the readout lines EL1 to RLh. The driving chip IC may be configured to drive the plurality of pixels PX (e.g., see FIG. 3) and the plurality of sensors FX. For example, the driving chip IC may include the data driver 100C2 (e.g., see FIG. 3) and the sensor controller 100C6.

Each of the data lines DL1 to DLm and the readout lines RL1 to RLh may extend from the first non-bending area NBA1 to the second non-bending area NBA2 via the bending area BA. Each of the data lines DL1 to DLm and the readout lines RL1 to RLh may be electrically connected to a pad unit (e.g., a pad area) disposed adjacent to the end of the second non-bending area NBA2. The pad unit may be disposed adjacent to an edge DPeg of the display panel DP. The pad unit may include display pads 100pd respectively connected to the data lines DL1 to DLm, sensor pads 101pd respectively connected to the readout lines RL1 to RLh, and touch pads 230pd respectively electrically connected to the first trace lines 231 and the second trace lines 232.

A flexible circuit film FCB may be electrically connected to the pad unit. The flexible circuit film FCB may be adhered to the pad unit through a conductive adhesive film or the like, and thus, the display panel DP may be electrically connected with the flexible circuit film FCB. A touch driving chip T-IC configured to drive the sensor layer 200 may be mounted on the flexible circuit film FCB.

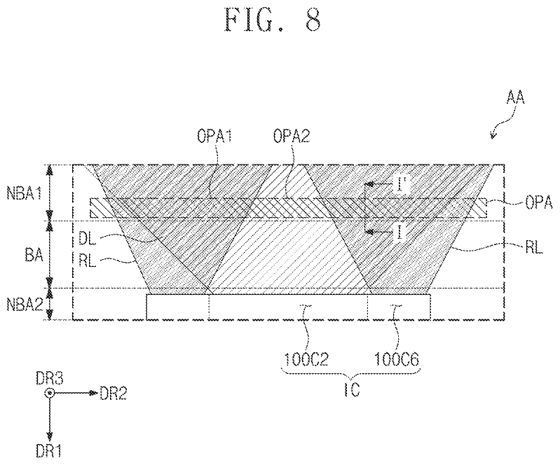

FIG. 8 is an enlarged plan view illustrating a portion of the display panel according to an embodiment of the present disclosure. FIG. 8 shows an enlarged view of the area AA shown in FIG. 7.

Referring to FIGS. 7 and 8, an open area OPA is defined in the peripheral area NDA of the display panel DP. The open area OPA may be defined between the active area DA and the bending area BA, and be adjacent to the bending area BA. In other words, the open area OPA may be defined in the first non-bending area NBA1 adjacent to the bending area BA. As will be described in more detail below, the open area OPA corresponds to an area from which an insulation layer of the circuit layer DP_CL (e.g., see FIG. 6) is partially removed.

The open area OPA may include a first open area OPA1 in which all of the readout lines RL and the data lines DL overlap with one another. The open area OPA may further include a second open area OPA2 in which either the readout lines RL, the data lines DL, or both do not overlap with one another, unlike in the first open area OPA1.

FIG. 9 is an enlarged cross-sectional view illustrating a portion of a display panel according to an embodiment of the present disclosure. FIG. 9 is a cross-sectional view corresponding to a cut line I-I′ of FIG. 8. For convenience of illustration, FIG. 9 shows a cross section according to the advancing direction of any one of the plurality of readout lines RL.

Referring to FIGS. 7 to 9, in the cross-section corresponding to the peripheral area NDA, the display panel DP includes the base layer BL, and a plurality of insulation layers IL-L, IL-U disposed on the base layer BL. Each of the plurality of insulation layer IL-L, IL-U may correspond to at least one insulation layer from among the first insulation layer 10 to the eighth insulation layers 80 described above with reference to FIG. 6.

The plurality of insulation layers IL-L, IL-U may include a lower insulation layer IL-L disposed on the base layer BL, and an upper insulation layer IL-U disposed on the lower insulation layer IL-L. The upper insulation layer IL-U includes an organic material.

The lower insulation layer IL-L may include a first lower insulation layer IL-L1, a second lower insulation layer IL-L2, and a third lower insulation layer IL-L3, which are sequentially disposed on the base layer BL. The upper insulation layer IL-U may include a first upper insulation layer IL-U1, a second upper insulation layer IL-U2, and a third upper insulation layer IL-U3. In FIG. 9, the lower insulation layer IL-L and upper insulation layer IL-U each have a three-layered structure, but the present disclosure is not limited thereto. The lower insulation layer IL-L and the upper insulation layer IL-U may each may have a two-layered structure or a four-layered structure.

The first lower insulation layer IL-L1, the second lower insulation layer IL-L2, and the third lower insulation layer IL-L3 included in the lower insulation layer IL-L may each include an inorganic material. For example, the first lower insulation layer IL-L1, the second lower insulation layer IL-L2, and the third lower insulation layer IL-L3 may each include at least one of aluminum oxide, titanium oxide, silicon oxide, silicon nitride, silicon oxynitride, zirconium oxide, or halfnium oxide.

The first upper insulation layer IL-U1, the second upper insulation layer IL-U2, and the third upper insulation layer IL-U3 included in the upper insulation layer IL-U may each include an organic material. For example, the first upper insulation layer IL-U1, the second upper insulation layer IL-U2, and the third upper insulation layer IL-U3 may each include a general purpose polymer such as Benzocyclobutene (BCB), polyimide, Hexamethyldisiloxane (HMDSO), Polymethylmethacrylate (PMMA), or Polystyrene (PS), a polymer derivative having a phenol group, an acryl-based polymer, an imide-based polymer, an allyl ether-based polymer, an amide-based polymer, a fluorine-based polymer, a p-xylene-based polymer, a vinylalcohol-based polymer, a suitable blend thereof, and/or the like.

Each of the lower insulation layer IL-L and the upper insulation layer IL-U may correspond to at least one insulation layer from among the first insulation layer 10 to the eighth insulation layers 80 described above with reference to FIG. 6. In an embodiment, the first lower insulation layer IL-L1 may correspond to the first insulation layer 10 or the second insulation layer 20 in FIG. 6. The second lower insulation layer IL-L2 may correspond to the fourth insulation layer 40 in FIG. 6. The third lower insulation layer IL-L3 may correspond to the fifth insulation layer 50 in FIG. 6. The first upper insulation layer IL-U1 may correspond to the sixth insulation layer 60 in FIG. 6. The second upper insulation layer IL-U2 may correspond to the seventh insulation layer 70 in FIG. 6. The third upper insulation layer IL-U3 may correspond to the sixth insulation layer 80 in FIG. 6.

In the bending area BA, at least one bending insulation layer BIL-U1, BIL-U2, BIL-U3 may be disposed. The bending insulation layers BIL-U1, BIL-U2, BIL-U3 may include a first bending insulation layer BIL-U1, a second bending insulation layer BIL-U2, and a third bending insulation layer BIL-U3. The first bending insulation layer BIL-U1 may correspond to the first upper insulation layer IL-U1. The second bending insulation layer BIL-U2 may correspond to the second upper insulation layer IL-U2. The third bending insulation layer BIL-U3 may correspond to the third upper insulation layer IL-U3.

The open area OPA is defined in the peripheral area NDA of the display panel DP. The open area OPA may be defined in the first non-bending area NBA1 adjacent to the being area BA. The open area OPA corresponds to an area in which at least portion of the insulation layers IL-L, IL-U included in the circuit layer is not disposed. The open area OPA may correspond to an area in which the upper insulation layer IL-U included in the circuit layer is not disposed. In the open area OPA, the first upper insulation layer IL-L1, the second upper insulation layer IL-L2, and the third upper insulation layer IL-L3 included in the upper insulation layer IL-U may not be disposed.

At least one dam structure DAM may be disposed in the open area OPA. The dam structure DAM may include a material that is same or substantially the same as that of at least a portion of the materials included in the upper insulation layer IL-U. The dam structure DAM may include at least one layer including the same or substantially the same material as that of at least one of the layers included in the upper layer IL-U.

The dam structure may include a plurality of dams. The dam structure DAM may include a first dam DAM1, a second dam DAM2, and a third dam DAM3. The first dam DAM1, the second dam DAM2, and the third dam DAM3 may be sequentially arranged along a direction away from the active area DA. In other words, the second dam DAM2 may be spaced apart farther from the active area DA in comparison to the first dam DAM1, and the first dam DAM1 may be disposed between the active area DA and the second dam DAM2. The third dam DAM3 may be spaced apart farther from the active area DA in comparison to the second dam DAM2, and the second dam DAM2 may be disposed between the first dam DAM1 and the third dam DAM3.

Each of the dam structures DAM may include a plurality of layers. In an embodiment, the dam structure DAM may include a two-layered structure or a three-layered structure. The first dam DAM1 may include a 1-1st layer IIL-1 and a 2-1st layer IIL2-1. The second dam DAM2 may include a 1-2nd layer IIL1-2 and a 2-2nd layer IIL2-2. The third dam DAM3 may include a 1-3rd dam IIL1-3, a 2-3rd dam IIL2-3, and a 3-3rd dam IIL3-3.

The first dam DAM1 and the second dam DAM2 may have the same or substantially the same level (e.g., height) as each other. The first dam DAM1 and the second dam DAM2 each may have a layer corresponding to at least one of the layers of the upper insulation layer IL-U. The first dam DAM1 and the second dam DAM2 may have layers respectively corresponding to the first upper insulation layer IL-U1 and the second upper insulation layer IL-U2. In an embodiment, the first dam DAM1 and the second dam DAM2 may each have a two-layered structure including the layers respectively corresponding to the first upper insulation layer IL-U1 and the second upper insulation layer IL-U2. The 1-1st layer IIL-1 and the 1-2nd layer IIL1-2 may include the same material as that of the first upper insulation layer IL-U1, and may be provided through the same or substantially the same processes. The 2-1st layer IIL-1 and the 2-2nd layer IIL2-2 may include the same material as that of the second upper insulation layer IL-U2, and may be provided through the same or substantially the same processes.

The third dam DAM3 may have a height higher than each of the first dam DAM1 and the second dam DAM2. The third dam DAM3 may have a layer corresponding to at least one of the layers of the upper insulation layer IL-U. The third dam DAM3 may have layers corresponding to the first upper insulation layer IL-U1 and the second upper insulation layer IL-U2. In an embodiment, the third dam DAM3 may have a three-layered structure including the layers respectively corresponding to the first upper insulation layer IL-U1, the second upper insulation layer IL-U2, and an additional layer on the top. The 1-3rd layer IIL1-3 may include the same material as that of the first upper insulation layer IL-U1, and may be provided through the same or substantially the same processes. The 2-3rd layer IIL2-3 may include the same material as that of the second upper insulation layer IL-U2, and may be provided through the same or substantially the same processes. The 3-3rd layer IIL3-3 may include a different material from that of the upper insulation layer IL-U.

A spacer may be defined between the plurality of dams DAM1, DAM2, DAM3 included in the dam structure DAM. Valley structures may be provided between the plurality of dams DAM1, DAM2, DAM3 in areas adjacent to the plurality of dams DAM1, DAM2, DAM3. The dam structure DAM is disposed in the peripheral area NDA of the display panel DP, and the valley structures defined between the plurality of dams DAM1, DAM2, DAM3 and adjacent to the plurality of dams DAM1, DAM2, DAM3 may prevent or substantially prevent an organic encapsulation layer TOL included in the encapsulation layer TFE from overflowing.

The circuit layer DP_CL according to an embodiment includes the readout line RL. The readout line RL may overlap with the open area OPA, and may be disposed on the lower insulation layer IL-L. At least a portion of the readout line RL may be disposed on the first upper insulation layer IL-U1. The readout line RL may include the same material as that of the second connection electrode CNE20 shown in FIG. 6, and may be provided through the same or substantially the same processes.

The circuit layer DP_CL includes an inorganic insulation pattern IIP overlapping with at least a portion of the readout line RL. The inorganic insulation pattern IIP may be disposed on at least a portion of the upper portion (e.g., the upper surface) and the lower portion (e.g., the lower surface) of the readout line RL. The inorganic insulation pattern IIP may contact at least one of the top surface or the bottom surface of the readout line RL. In an embodiment, the inorganic insulation pattern IIP may include a first inorganic insulation pattern IIP1 disposed on the lower portion of the readout line RL, and a second inorganic insulation pattern IIP2 disposed on the upper portion of the readout line RL. The readout line RL may be directly disposed on the first inorganic insulation layer IIP1, and the second insulation layer IIP2 may be directly disposed on the readout line RL. The inorganic insulation pattern IIP may include at least one of silicon nitride, silicon oxynitride, silicon oxide, titanium oxide, or aluminum oxide.

The circuit layer DP_CL may further include conductive layers CDL1, CDL2 overlapping with at least a portion of the readout line RL. The conductive layers CDL1, CDL2 may include a first conductive layer CDL1 disposed under the readout line RL, and a second conductive layer CDL2 disposed over the readout line RL. The first conductive layer CDL1 may include the same material as that of the first connection electrode CNE10 shown in FIG. 6, and may be provided through the same or substantially the same processes. The second conductive layer CDL2 may include the same material as that of the third connection electrode CNE30 shown in FIG. 6, and may be provided through the same or substantially the same processes.

The conductive layers CDL1, CDL2 may be spaced apart from the readout line RL with the inorganic insulation pattern IIP interposed therebetween. The first conductive layer CDL1 may be spaced apart from the readout line RL with the first inorganic insulation pattern IIP1 interposed therebetween. The second conductive layers CDL2 may be spaced apart from the readout line RL with the second inorganic insulation pattern IIP2 interposed therebetween. The first inorganic insulation layer IIP1 may be directly disposed on the first conductive layer CDL1. The second conductive layer CDL2 may be directly disposed on the second inorganic insulation pattern IIP2. The conductive layers CDL1, CDL2 may be referred to as a metal shield layer, a metal layer, a pattern layer, a metal pattern, a shield pattern, or the like.

The circuit layer DP_CL may further include the data line DL, and at least a portion of the data line DL may overlap with the open area OPA. The data line DL may be covered with at least one layer of the lower insulation layer IL_L. The data line DL may include a first layer data line DL-1 disposed on the first lower insulation layer IL-L1, and a second layer data line DL-2 disposed on the second lower insulation layer IL-L2. Any one of the first layer data line DL-1 and the second layer data line DL-2 may be omitted as needed or desired.

The first conductive layer CDL1 may be disposed between the data line DL and the readout line RL. In the open area OPA, the first conductive layer CDL1 may overlap with each of the data line DL and the readout line RL.

The first conductive layer CDL1 may be applied with a constant voltage or the ground voltage. For example, the first conductive layer CDL1 may be provided with the first driving voltage ELVDD (e.g., see FIG. 5), the second driving voltage ELVSS, the first initialization voltage VINT1, or the second initialization voltage VINT2, but the present disclosure is not particularly limited thereto. Accordingly, an interference between a signal provided to the data line DL and a signal provided to the readout line RL may be blocked by the first conductive layer CDL1.

In the open area OPA, a portion of the encapsulation layer TFE may be disposed over the circuit layer DP_CL. As described above, the encapsulation layer TFE may cover the light emitting element ED (e.g., see FIG. 6) and the light sensing element OPD. The encapsulation layer TFE may include two inorganic encapsulation layers TIL1, TIL2, and an organic encapsulation layer TOL disposed therebetween.

On the encapsulation layer TFE, the first sensor conductive layer 202 included in the sensor layer 200 (e.g., see FIG. 6) may be disposed. The first sensor conductive layer 202 may correspond to, for example, either the first trace lines 231, the second trace lines 232, or both. In some embodiments, a sensor base layer may be further included between the encapsulation layer TFE and the first sensor conductive layer 202.

The second conductive layer CDL2 may be disposed between the readout line RL and the first sensor conductive layer 202. In the open area OPA, the second conductive layer CDL2 may overlap with each of the readout line RL and the first sensor conductive layer 202.

The second conductive layer CDL2 may be applied with a constant voltage or the ground voltage. For example, the second conductive layer CDL2 may be provided with the first driving voltage ELVDD (e.g., see FIG. 5), the second driving voltage ELVSS, the first initialization voltage VINT1, or the second initialization voltage VINT2, but the present disclosure is not particularly limited thereto. Accordingly, an interference between a signal provided to the first sensor conductive layer 202 and a signal provided to the readout line RL may be blocked by the second conductive layer CDL2.

In the display panel of an embodiment, the first conductive layer is disposed between the readout line electrically connected to the light sensing element and the data line electrically connected to the light emitting element. The second conductive layer is disposed between the readout lines and the sensor conductive layer corresponding to the trace lines. In the display panel of an embodiment, the first conductive layer and the second conductive layer may each be applied with a constant voltage or the ground voltage to block the interference between a signal provided to the data lines and a signal provided to the readout lines, and to block the interference between a signal provided to the readout lines and a signal provided to the trace lines. Accordingly, noise that may occur in the signals transferred to each of the lines may be reduced or removed.

In the display panel of an embodiment, an open area in which an organic insulation layer is not disposed may be defined for preventing or substantially preventing the encapsulation layer from overflowing. In the open area, the organic insulation layer, for distinguishing the readout line from the first conductive layer and the second conductive layer, may be omitted. However, the display panel of an embodiment may further include an inorganic insulation pattern that is disposed to overlap with the open area and at least a portion of the readout lines, and may have the structure in which the inorganic insulation pattern is disposed over and under the readout lines. Accordingly, even in the open area, an insulation structure may be implemented between the readout lines and each of the first conductive layer and the second conductive layer for signal shielding, and thus, a signal transfer structure may be implemented in which the occurrence of noise or the like is reduced or removed.

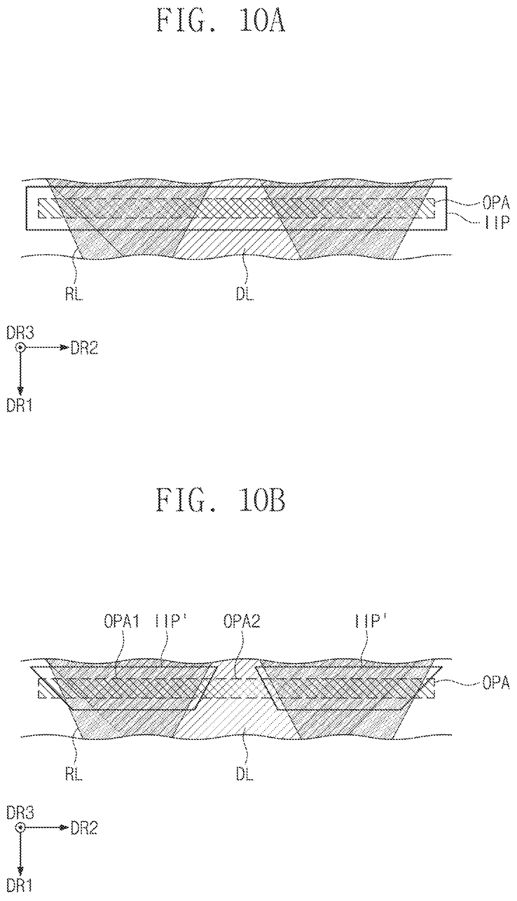

FIGS. 10A and 10B are enlarged plan views illustrating a portion of a display panel according to one or more embodiments of the present disclosure. In FIGS. 10A and 10B, a disposition relationship between the open area OPA shown in FIG. 8 and the inorganic insulation pattern IIP disposed to overlap with the open area OPA is mainly illustrated.

Referring to FIGS. 8, 9, and 10A, the inorganic insulation pattern IIP may be disposed to overlap with at least the open area OPA in a plan view. As shown in FIG. 10A, the inorganic insulation pattern IIP may be disposed to overlap with the entire open area OPA. Each of the first inorganic insulation pattern IIP1 and second inorganic insulation patter IIP2 included in the inorganic insulation pattern IIP may be disposed to overlap with the entire open area OPA.

A portion of the inorganic insulation pattern IIP may also be disposed in another area adjacent to the open area OPA. A portion of the inorganic insulation pattern IIP may also be disposed in another portion of the first non-bending area NBA1 adjacent to the open area OPA. A portion of the inorganic insulation pattern IIP may also be disposed in the bending area BA. Unlike that shown in FIG. 10A, the inorganic insulation pattern IIP may be patterned to overlap with only the open area OPA.

Referring to FIG. 10B, unlike that shown in FIG. 10A, an inorganic insulation pattern IIP′ may be patterned to overlap with portions (e.g., only portions) of the open area OPA. The open area OPA may include a first open area OPA1 in which all of the readout lines RL and the data lines DL overlap with each other, and a second open area OPA2 in which either the readout lines RL, the data lines DL, or both do not overlap with each other. The inorganic insulation pattern IIP′ may be disposed to overlap with the first open area OPA1, and may not overlap with at least a portion of the second open area OPA2. The inorganic insulation pattern IIP′ may be disposed to overlap with the entire first open area OPA1. The inorganic insulation pattern IIP′ may be patterned to overlap with only the first open area OPA1 in which all of the readout lines RL and data lines DL overlap with each other.

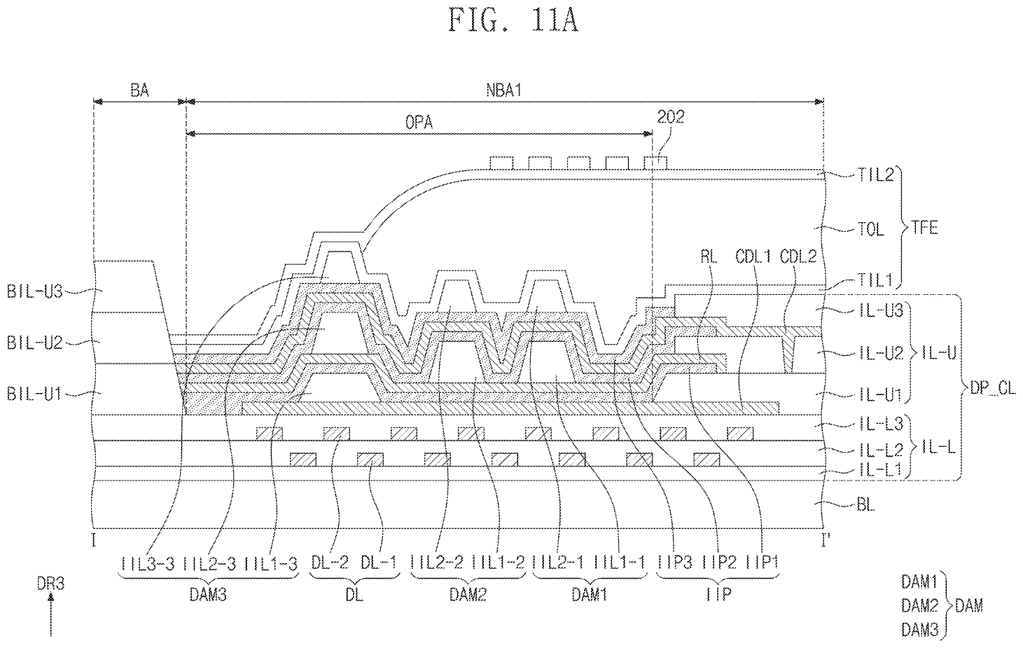

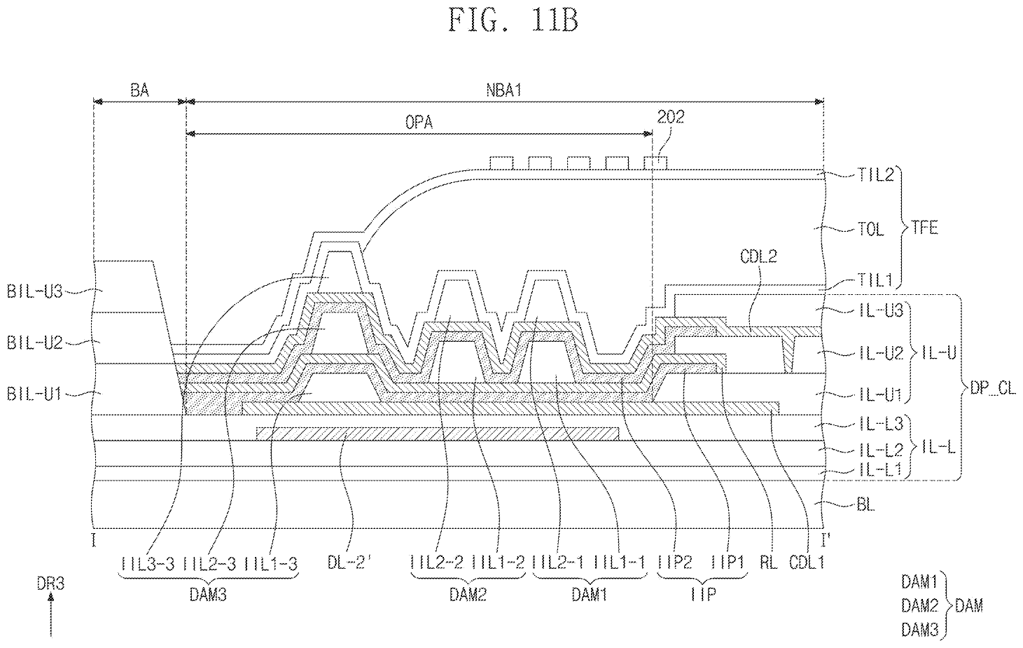

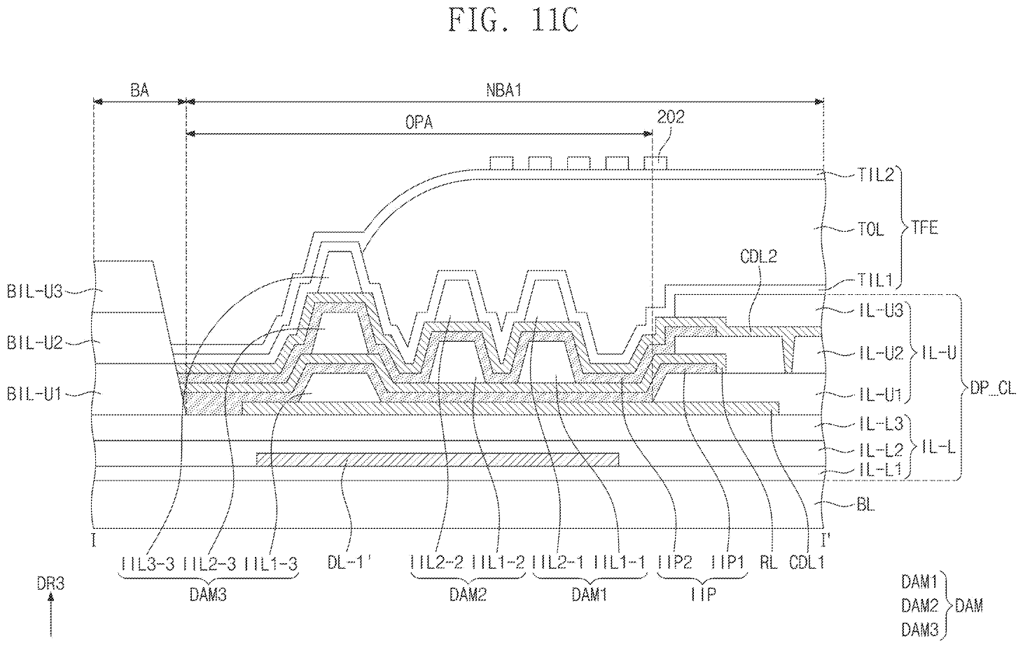

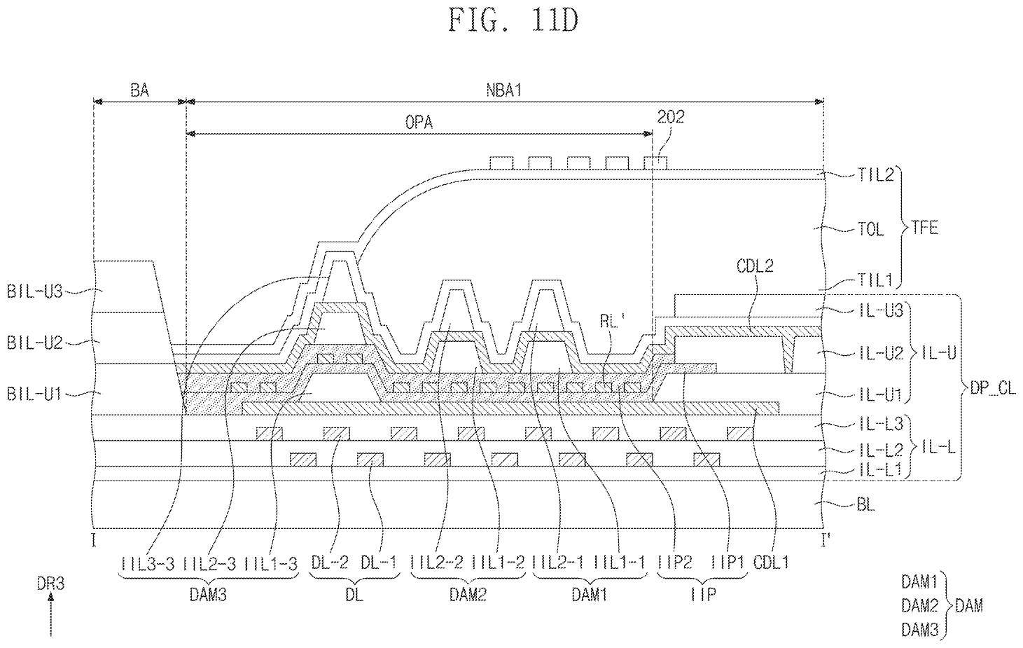

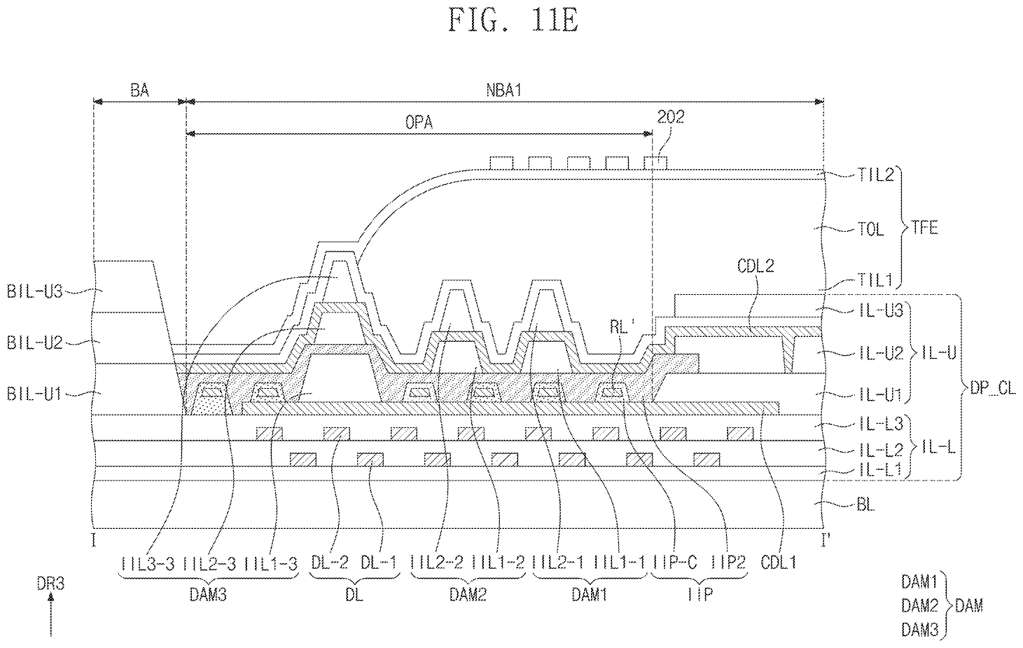

FIGS. 11A through 11E are enlarged cross-sectional views of a portion of the display panel according to one or more embodiments of the present disclosure. Each of FIGS. 11A through 11E shows an embodiment of a display panel different from that of the embodiment shown in FIG. 9. In FIGS. 11A to 11E, the same or like reference numerals are used to indicate the same or substantially the same (or similar) components as those described above with reference to FIG. 9, and thus, the difference may be mainly described hereinafter, and redundant description may not be repeated.

Referring to FIG. 11A, the inorganic insulation pattern IIP may further include a third inorganic insulation pattern IIP3 disposed over the second conductive layer CDL2, in addition to the first inorganic insulation pattern IIP1 disposed under the readout line RL and the second inorganic second insulation pattern IIP2 disposed over the readout line RL. The third inorganic insulation layer IIP3 may be directly disposed on the second conductive layer CDL2. The third inorganic insulation layer IIP3 may cover the second conductive layer CDL2 to insulate the second conductive layer CDL2 from another configuration disposed thereover.

Referring to FIGS. 8, 11B, and 11C, unlike that shown in FIG. 9, the extension direction of a portion of the data lines DL-1′, DL-2′ may be the same or substantially the same as that of a portion of the readout line RL. In other words, as illustrated in FIGS. 11B and 11C, in a cross section, the extension directions of one of the data lines DL-1′, DL-2′ and one readout line RL may be the same or substantially the same as each other. As shown in FIG. 11B, the data line having the same or substantially the same extension direction as that of the readout line RL may be the second layer data line DL-2′ disposed on the second lower insulation layer IL-L2. As another example, as shown in FIG. 11C, the data line having the same or substantially the same extension direction as that of the readout line RL may be the first layer data line DL-1′ disposed on the first lower insulation layer IL-L1.

Unlike that shown in FIG. 9, FIGS. 11D and 11E show cross sections according to a direction that is not the advancing direction of any one of the plurality of readout lines, and illustrates cross sections according to a direction crossing the plurality of readout lines RL′.

Referring to FIGS. 8 and 11D, the inorganic insulation pattern IIP is disposed on at least a portion of the upper portion or the lower portion of each of the plurality of readout lines RL′ disposed to overlap with the open area OPA. In the open area OPA, the inorganic insulation pattern IIP is disposed to overlap with each of the plurality of readout lines RL′.

The inorganic insulation pattern IIP may include the first inorganic insulation pattern IIP1 disposed on the lower portion of the plurality of readout lines RL′, and the second inorganic insulation pattern IIP2 disposed on the upper portion of the plurality of readout line RL′. The plurality of readout lines RL′ may be directly disposed on the first inorganic insulation pattern IIP1, and the second inorganic insulation pattern IIP2 may be directly disposed on the plurality of readout lines RL′. The second inorganic insulation pattern IIP2 may cover the top surface and side surfaces of the plurality of readout lines RL′. The second inorganic insulation pattern IIP2 may fill spacers between the plurality of readout lines RL′.

Referring to FIGS. 8 and 11E, the inorganic insulation pattern IIP may include unit inorganic insulation patterns IIP-C that cover the plurality of readout lines RL′, respectively. The unit inorganic insulation patterns IIP-C may have shapes surrounding the plurality of readout lines RL′, respectively, in a plan view.

Each of the unit inorganic insulation patterns IIP-C may entirely surround one corresponding readout line RL′ from among the plurality of readout lines RL′. As shown in FIG. 11E, the unit inorganic insulation pattern IIP-C may be disposed to cover the top surface, the bottom surface, and the side surfaces of the corresponding readout line RL′. The second inorganic insulation pattern IIP2 may be disposed on the plurality of readout lines RL′ surrounded by the unit inorganic insulation patterns. The second inorganic insulation pattern IIP2 may be provided in a layer structure to cover the top of each of the unit inorganic insulation patterns IIP-C. However, the present disclosure is not limited thereto, and the second inorganic insulation pattern IIP2 may be omitted as needed or desired.

According to one or more embodiments of the present disclosure, the data lines and the readout lines of the display panel may extend to the peripheral area adjacent to the active area in the first direction. Accordingly, the driver for driving the sensors and the driver for driving the pixels may be disposed at positions spaced apart (e.g., separated) from each other in one direction on the basis of the active area. As a result, the area of the fan-out area may be reduced, and the area of the peripheral area may be reduced. In addition, because a portion (e.g., only a portion) of the peripheral area positioned in a lower end on the basis of the active area may be bent, interference between the bent portion of the display panel and other sensors (e.g., a location sensor, a vibration sensor, and/or the like) disposed in the bottom of the display panel may be reduced.

According to one or more embodiments of the present disclosure, in the display panel, while the conductive layers for shielding signals are provided between the readout lines, the data lines, and the trace lines, an inorganic insulation pattern disposed to overlap with the open area and overlapping with at least a portion of the readout lines may also be provided to implement, in the open area, an insulation structure between the readout lines and the conductive layers for shielding signals. Accordingly, noise that may occur in signals transferred to the readout lines and signals transferred to the data lines and trace lines may be reduced or removed.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display panel comprising:
an active area;
a peripheral area adjacent to the active area;
a circuit layer comprising a plurality of insulation layers comprising:
at least one lower insulation layer; and
at least one upper insulation layer comprising an inorganic material; and
an element layer comprising a plurality of light emitting elements in the active area, and a plurality of light sensing elements in the active area,
wherein the peripheral area comprises an open area in which the at least one upper insulation layer is not disposed, and
wherein the circuit layer comprises:
a plurality of readout lines electrically connected with the plurality of light sensing elements, and extending from the active area to the peripheral area; and
an inorganic insulation pattern overlapping with the open area and at least a portion of the plurality of readout lines.

2. The display device of claim 1, wherein:
the circuit layer further comprises a first conductive layer under each of the plurality of readout lines; and
the inorganic insulation pattern comprises a first inorganic insulation pattern between the plurality of readout lines and the first conductive layer.

3. The display device of claim 2, wherein the first conductive layer is configured to be applied with a constant voltage or ground voltage.

4. The display device of claim 2, wherein the inorganic insulation pattern further comprises a second inorganic insulation pattern over the plurality of readout lines.

5. The display device of claim 4, wherein:
the first inorganic insulation pattern is directly on the first conductive layer;
the plurality of readout lines are directly on the first inorganic insulation pattern; and
the second inorganic insulation pattern is directly on the plurality of readout lines.

6. The display device of claim 4, wherein:
the circuit layer further comprises a second conductive layer over each of the plurality of readout lines; and
the second inorganic insulation pattern is located between the plurality of readout lines and the second conductive layer.

7. The display device of claim 6, wherein the second conductive layer is configured to be applied with a constant voltage or ground voltage.

8. The display device of claim 6, wherein the inorganic insulation pattern further comprises a third inorganic insulation pattern over the second conductive layer.

9. The display device of claim 6, wherein the display panel further comprises an encapsulation layer on the element layer, and covering the plurality of light emitting elements and the plurality of light sensing elements, and
wherein the encapsulation layer is located on the second conductive layer in the open area.

10. The display device of claim 9, wherein the display panel further comprises a sensor layer directly on the encapsulation layer, and comprising at least one sensor conductive layer.

11. The display device of claim 10, wherein the second conductive layer is located between at least a portion of the sensor conductive layer and the plurality of readout lines.

12. The display device of claim 2, wherein:
the circuit layer further comprises a plurality of data lines electrically connected to the plurality of light emitting elements, and extending to the peripheral area; and
the first conductive layer is located between the plurality of readout lines and the plurality of data lines.

13. The display device of claim 12, wherein the open area comprises:
a first open area in which the plurality of readout lines overlap with the plurality of data lines; and
a second open area in which either the plurality of readout lines, the plurality of data lines, or both do not overlap with each other, and
wherein the inorganic insulation pattern overlaps with the first open area.

14. The display device of claim 12, wherein the plurality of data lines are covered by the lower insulation layer.

15. The display device of claim 1, wherein the circuit layer further comprises a dam structure overlapping with the open area, and comprising at least one layer comprising the same material as that of the upper insulation layer.

16. The display device of claim 1, wherein:
the peripheral area further comprises a bending area bent about a bending axis parallel to one direction; and
the open area is located between the active area and the bending area.

17. A display device comprising:
a display panel comprising:
an active area;
a peripheral area adjacent to the active area;
a circuit layer comprising a plurality of insulation layers and at least one line, the plurality of insulating layers comprising at least one upper insulation layer comprising an inorganic material; and
an element layer comprising a plurality of light emitting elements in the active area, and a plurality of light sensing elements in the active area,
wherein the peripheral area comprises an open area in which the at least one upper insulation layer is not disposed, and
wherein the circuit layer comprises:
a plurality of data lines electrically connected to the plurality of light emitting elements, and extending to the peripheral area;
a plurality of readout lines electrically connected with the plurality of light sensing elements, and extending from the active area to the peripheral area; and
an inorganic insulation pattern overlapping with the open area, and at least a portion of the inorganic insulation pattern is located between the plurality of data lines and the plurality of readout lines.

18. A display device comprising:
a display panel comprising:
an active area;
a peripheral area adjacent to the active area;
a circuit layer comprising a plurality of insulation layers and at least one line, the plurality of insulation layers comprising at least one upper insulation layer comprising an inorganic material; and
an element layer comprising a plurality of light emitting elements in the active area, and a plurality of light sensing elements in the active area,
wherein the peripheral area comprises an open area in which the at least one upper insulation layer is not disposed, and
wherein the circuit layer comprises:
a plurality of readout lines electrically connected with the plurality of light sensing elements, and extending from the active area to the peripheral area; and
an inorganic insulation pattern overlapping with the open area, and contacting at least one of a top surface or a bottom surface of the plurality of readout lines.

19. The display device of claim 18, wherein:
the circuit layer further comprises a first conductive layer under each of the plurality of readout lines; and
the inorganic insulation pattern comprises:
a first inorganic insulation pattern between the plurality of readout lines and the first conductive layer; and
a second inorganic insulation pattern over the plurality of readout lines.

20. The display device of claim 19, wherein:
the first inorganic insulation pattern is directly on the first conductive layer;
the plurality of readout lines are directly on the first inorganic insulation pattern; and
the second inorganic insulation pattern is directly on the plurality of readout lines.
